(19) United States
(12) Patent Application Publication
(10) Pub. No.: US 2025/0112179 A1
(43) Pub. Date: Apr. 3, 2025

(54) TECHNOLOGIES FOR A COAXIAL INDUCTOR IN A GLASS CORE

(71) Applicant: Intel Corporation, Santa Clara, CA (US)

(72) Inventors: Brandon Christian Marin, Gilbert, AZ (US); Tarek A. Ibrahim, Mesa, AZ (US); Mohammad Mamunur Rahman, Gilbert, AZ (US); Srinivas V. Pietambaram, Chandler, AZ (US); Sashi Shekhar Kandanur, Phoenix, AZ (US)

(73) Assignee: Intel Corporation, Santa Clara, CA (US)

(21) Appl. No.: 18/477,098

(22) Filed: Sep. 28, 2023

(51) Int. Cl. H01L 23/64; H01F 17/00; H01F 17/06; H01L 23/15; H01L 23/498

(52) U.S. Cl. CPC H01L 23/645; H01F 17/0013; H01F 17/06; H01L 23/15; H01L 23/49822; H01F 2017/002; H01F 2017/067

(57) ABSTRACT

Techniques for a coaxial inductor in a glass core are disclosed. In an illustrative embodiment, an inductor is positioned in a cavity of a glass core. The inductor includes a conductive via extending through the glass core surrounded by a magnetic material. A buffer layer is positioned between the edges of the cavity of the glass core and the inductor. The buffer can prevent or mitigate any stress caused by changes in temperature and different coefficients of thermal expansion of the glass core and the inductor. The inductor may form part of a fully integrated voltage regulator (FIVR), which provides a stable voltage source to a semiconductor die such as a processor.

### BACKGROUND

Packaged semiconductor dies are ubiquitous in modern electronics. A substrate in a package can have a large number of connections in multiple layers connecting different components. In some cases, a package may include a fully integrated voltage regulator to provide efficient power delivery to semiconductor dies. A voltage regulator may include an inductor, which may take up a relatively large amount of space.

### BRIEF DESCRIPTION OF THE DRAWINGS

FIG. 1 is an isometric view of one embodiment of a substrate with a glass core and a coaxial inductor.

FIG. 2 is a top-down view of the substrate of FIG. 1.

FIG. 3 is a cross-sectional view of the substrate of FIG. 1

FIG. 4 is a cross-sectional view of the substrate of FIG. 1.

FIG. 5 is a cross-sectional view of an integrated circuit component that includes the substrate of FIG. 1.

FIGS. 6 and 7 are a simplified flow diagram of at least one embodiment of a method for manufacturing a system with a glass substrate with a coaxial inductor.

FIG. 8 is a cross-sectional view of one embodiment of a substrate at one step of the method of FIGS. 6 and 7.

FIG. 9 is a cross-sectional view of one embodiment of a substrate at one step of the method of FIGS. 6 and 7.

FIG. 10 is a cross-sectional view of one embodiment of a substrate at one step of the method of FIGS. 6 and 7.

FIG. 11 is a cross-sectional view of one embodiment of a substrate at one step of the method of FIGS. 6 and 7.

FIG. 12 is a cross-sectional view of one embodiment of a substrate at one step of the method of FIGS. 6 and 7.

FIG. 13 is a cross-sectional view of one embodiment of a substrate at one step of the method of FIGS. 6 and 7.

FIG. 14 is a cross-sectional view of one embodiment of a substrate at one step of the method of FIGS. 6 and 7.

FIG. 15 is a cross-sectional view of one embodiment of a substrate at one step of the method of FIGS. 6 and 7.

FIG. 16 is a cross-sectional view of one embodiment of a substrate at one step of the method of FIGS. 6 and 7.

FIG. 17 is a cross-sectional view of one embodiment of a substrate at one step of the method of FIGS. 6 and 7.

FIG. 18 is a cross-sectional view of one embodiment of a substrate at one step of the method of FIGS. 6 and 7.

FIG. 19 is a cross-sectional view of one embodiment of a substrate at one step of the method of FIGS. 6 and 7.

FIG. 20 is a cross-sectional view of one embodiment of a substrate at one step of the method of FIGS. 6 and 7.

FIG. 21 is a cross-sectional view of one embodiment of a substrate at one step of the method of FIGS. 6 and 7.

FIG. 22 is a cross-sectional view of one embodiment of a substrate at one step of the method of FIGS. 6 and 7.

FIG. 23 is a cross-sectional view of one embodiment of a substrate at one step of the method of FIGS. 6 and 7.

FIG. 24 is a cross-sectional view of one embodiment of a substrate with a glass core and a coaxial inductor.

FIG. 25 is a cross-sectional view of one embodiment of a substrate with a glass core and a coaxial inductor.

FIG. 26 is a top view of a wafer and dies that may be included in a microelectronic assembly, in accordance with any of the embodiments disclosed herein.

FIG. 27 is a cross-sectional side view of an integrated circuit device that may be included in a microelectronic assembly, in accordance with any of the embodiments disclosed herein.

FIGS. 28A-28D are perspective views of example planar, gate-all-around, and stacked gate-all-around transistors.

FIG. 29 is a cross-sectional side view of an integrated circuit device assembly that may include a microelectronic assembly, in accordance with any of the embodiments disclosed herein.

FIG. 30 is a block diagram of an example electrical device that may include a microelectronic assembly, in accordance with any of the embodiments disclosed herein.

### DETAILED DESCRIPTION OF THE DRAWINGS

In the illustrative embodiment disclosed herein, a system includes a substrate with a glass core as part of an integrated circuit component, such as a processor. The illustrative integrated circuit component includes a coaxial inductor in the glass core. To mitigate stress due to, e.g., a mismatch in the coefficient of thermal expansion (CTE), a buffer layer surrounds the coaxial inductor that is more flexible than the glass core. The inductor may be used for any suitable purpose, such as a fully integrated voltage regulator (FIVR).

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/−5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

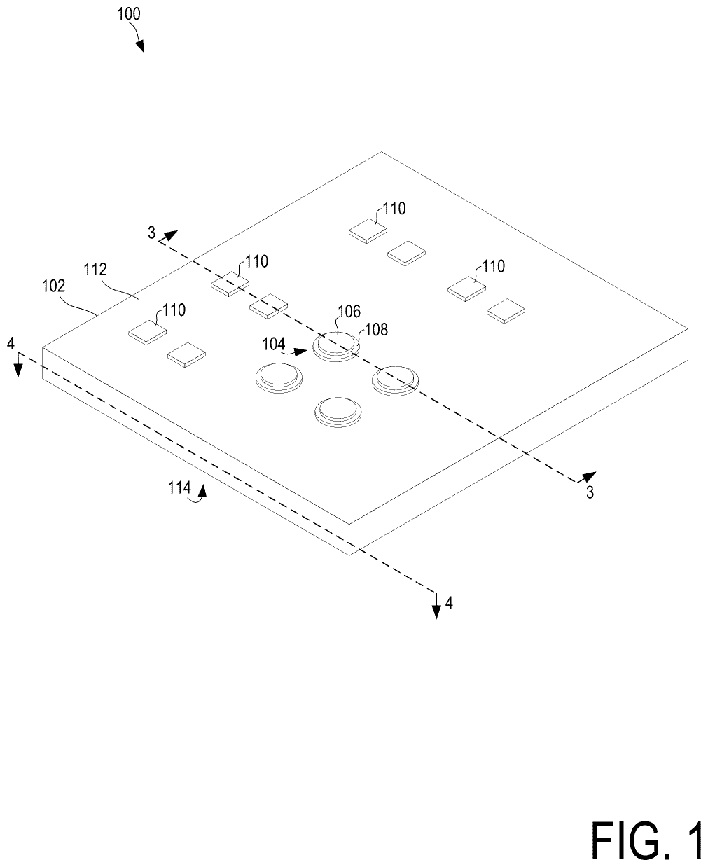

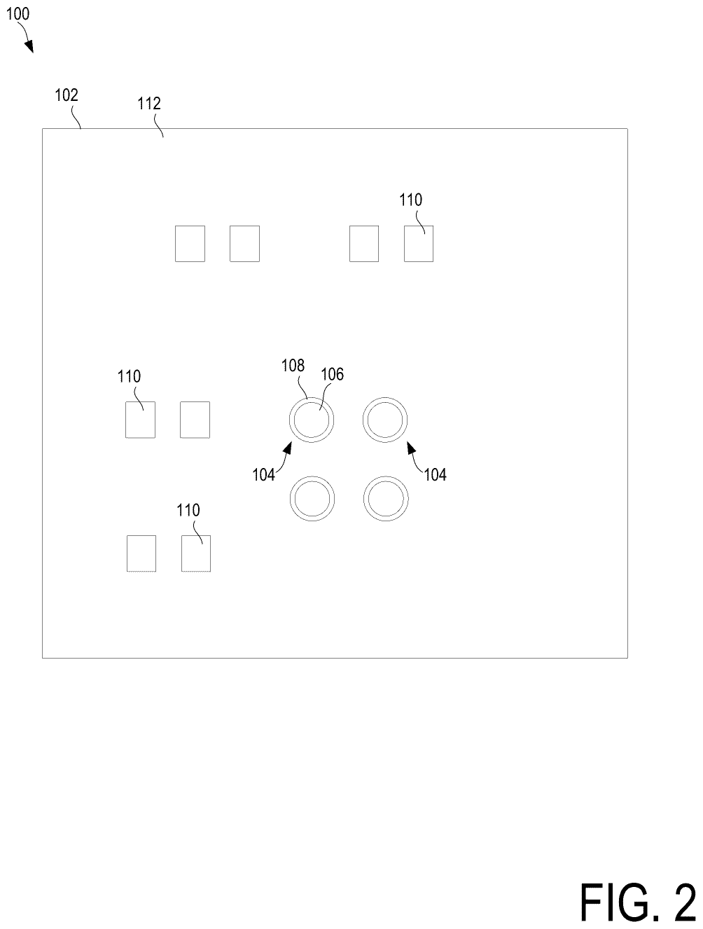

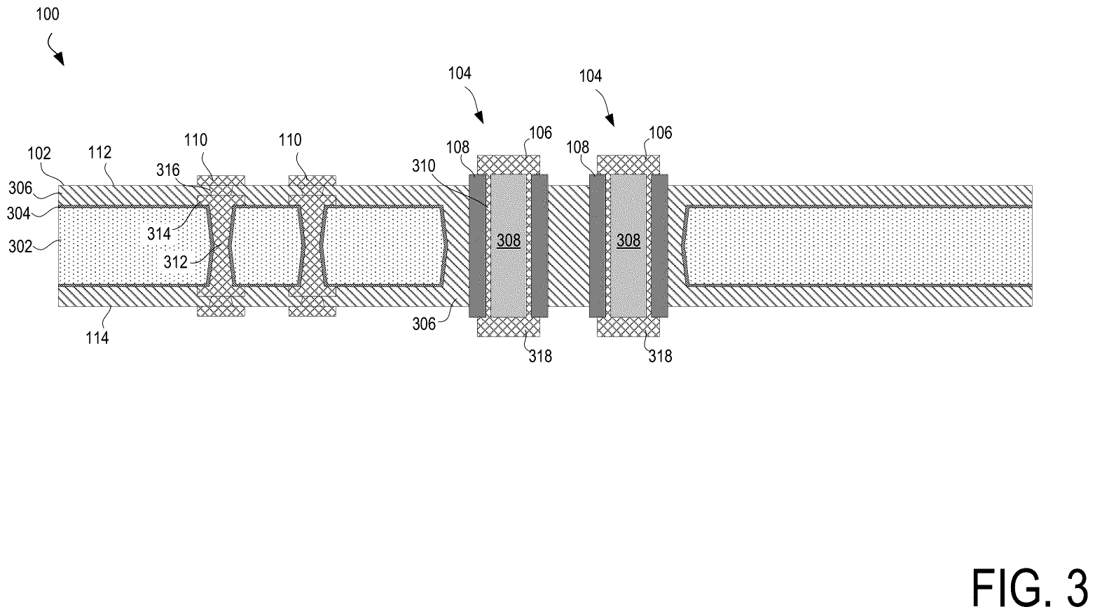

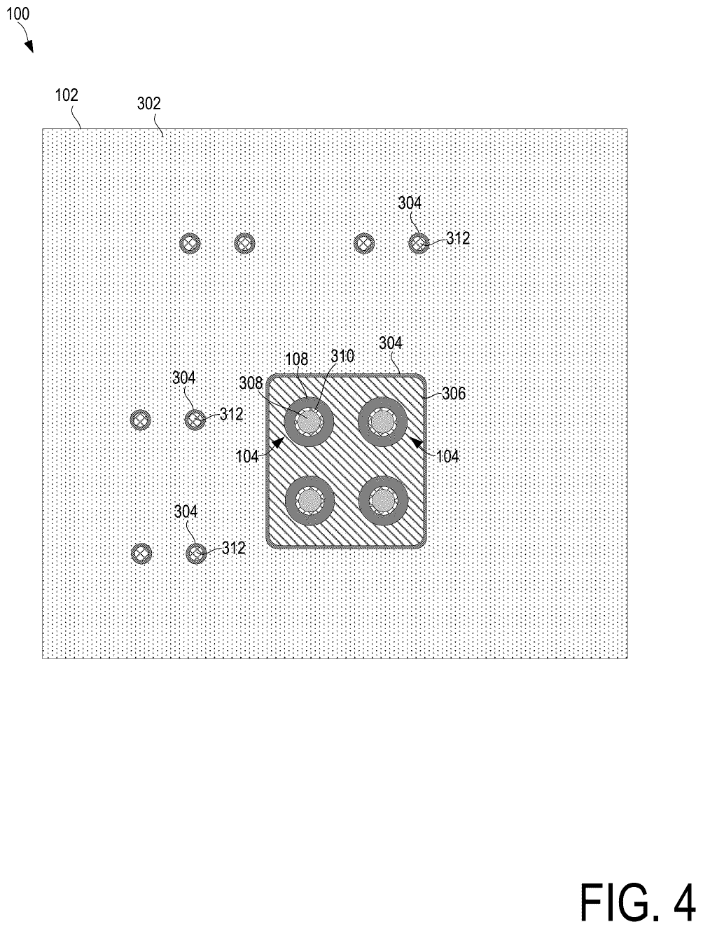

Referring now to FIGS. 1-4, in one embodiment, a system 100 includes a substrate 102 with a glass core 302. FIG. 1 shows an isometric view of the system 100, FIG. 2 shows a top-down view of the system 100, FIG. 3 shows a cross-sectional side view of the system 100 taken at the line 3 shown in FIG. 1, and FIG. 4 shows a cross-sectional top view of the system 100 taken at the line 4 shown in FIG. 1.

The illustrative system 100 includes one or more inductors 104 defined in the substrate 102 and glass core 302. The inductors 104 include a conductive via 310 extending from a pad 106 above a top surface 112 of the substrate 102 to a pad 318 below a bottom surface 114 of the substrate 102. In an illustrative embodiment, the conductive via 310 is a hollow cylinder filled with a plug 308. A magnetic material 108 surrounds the via 310. The magnetic material 108 increases the inductance of the inductor 104.

In an illustrative embodiment, some or all of the components of the inductor 104, such as the via 310, the plug 308, or the magnetic material 108 may have different characteristics than the glass core 302, which may cause issues if the components of the inductor 104 touched the glass core 302. For example, the glass core 302 may have a different coefficient of thermal expansion from the components of the inductor 104. If the inductor 104 was directly adjacent the glass core 302, a change in temperature may cause stress at the interface, possibly damaging the inductor 104 or the glass core 302.

In order to prevent such an occurrence, a buffer layer 306 surrounds the inductor 104, separating it from the glass core 302. The buffer layer 306 is relatively flexible and is able to accommodate different rates of expansion between the glass core 302 and the inductor 104. As such, the buffer layer 306 can relieve stress between the glass core and the inductor 104.

The substrate 102 may include additional components, such as pads 110. The pads 110 may be connected by vias 316 to a buried pad 314. The buried pad 314 can be connected to the other side of the glass core 302 through a through-glass via 312. The substrate 102 may include additional components such as additional pads, traces, vias, more inductors, etc.

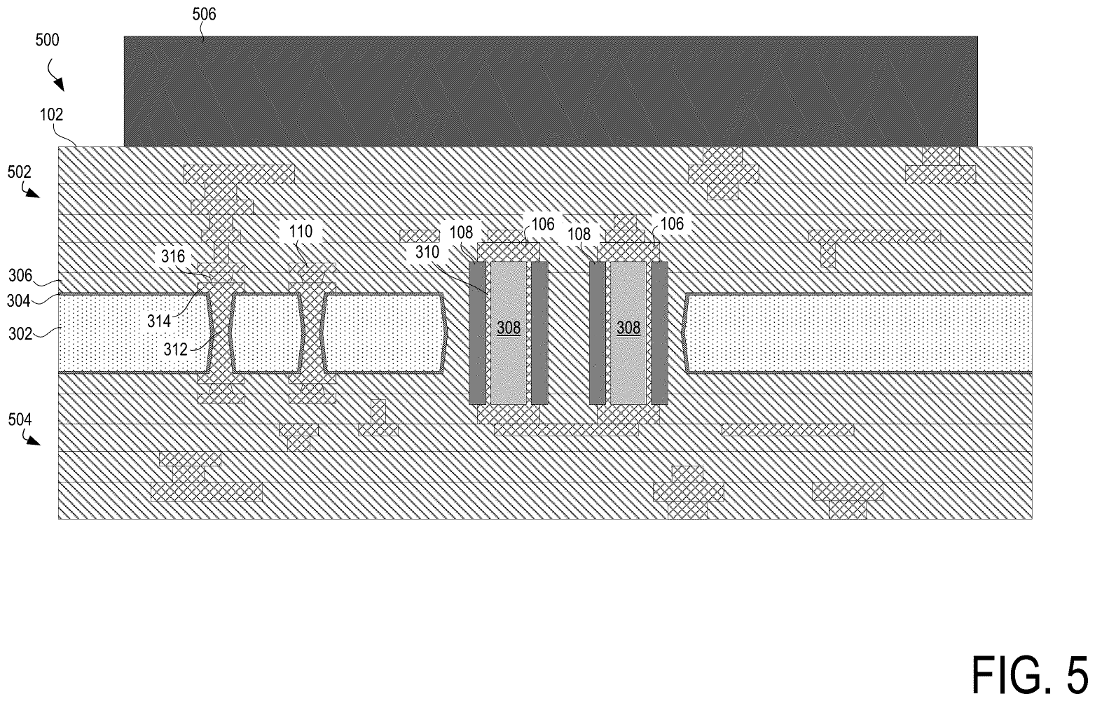

It should be appreciated that the substrate 102 shown in FIGS. 1-4 is a substrate 102 at one possible stage of manufacture. In use, the substrate 102 may have additional layers added to it and/or may have additional components mounted on it. For example, referring now to FIG. 5, an integrated circuit component 500 may include the substrate 102 with the glass core 302 and the inductor 104. The integrated circuit component 500 may include build-up layers 502 and/or 504 that are added to the substrate 102 using any suitable technique, such as semi-additive processing. The build-up layers 502 and/or 504 may include device layers and/or interconnect layers. The build-up layers 502 may include interconnect structure, vias, pads, traces, active components such as transistors, some or all of the components of a FIVR, and/or the like. In the illustrative embodiment, one or more semiconductor dies 506 are adjacent a top surface of the top build-up layer 502. The semiconductor die 506 may be, e.g., a processor die, a memory die, a network die, a field-programmable gate array (FPGA) die, an application-specific integrated circuit (ASIC) die, a photonic integrated circuit, etc. The total thickness of the substrate 102 with the build-up layers 502, 504 may be any suitable thickness, such as 300-2,000 micrometers. The semiconductor die 506 may have any suitable thickness, such as 100-5,000 micrometers.

In some embodiments, the inductor 104 is connected to other components of a fully integrated voltage regulator (FIVR). The FIVR may include components such as capacitors transistors, resistors, etc. Some or all of the components of the FIVR may be adjacent the glass core 302, may be located on build-up layers 502, 504 of the substrate 102, or may be located on the semiconductor die 506. A relatively large amount of current, such as 1-10 amps, may be able to flow through the inductor 104, facilitating the FIVR in regulating voltage to components of the system 500 in FIG. 5, such as the die 506. The FIVR may provide voltage and/or power to components of the system 500, such as the semiconductor die 506. In an illustrative embodiment, the inductor 104 may be below the semiconductor die 506 in order to reduce the trace path length between the inductor 104 and the semiconductor die 506.

Referring back to FIGS. 1-4, the illustrative glass core 302 is silicon oxide glass. In other embodiments, the glass core 302 may be made of any suitable material that may be crystalline, non-crystalline, amorphous, etc., such as fused silicon, borosilicate, sapphire, yttrium aluminum garnet, etc. The glass core 302 may be, e.g., aluminosilicate glass, borosilicate glass, alumino-borosilicate glass, silica, fused silica. The glass core 302 may include one or more additives, such as Al2O3, B2O3, MgO, CaO, SrO, BaO, SnO2, Na2O, K2O, SrO, P2O3, ZrO2, Li2O, Ti, and Zn. The glass core 302 may comprise silicon and oxygen, as well as any one or more of aluminum, boron, magnesium, calcium, barium, tin, sodium, potassium, strontium, phosphorus, zirconium, lithium, titanium, and zinc. The glass core 302 may include at least 20-40 percent silicon by weight, at least 20-40 percent oxygen by weight, and at least 5 percent aluminum by weight. For example, some embodiments of the glass core 302 may include, e.g., at least 20-23 percent silicon and at least 20-26 percent oxygen by weight. The glass core 302 may have any suitable thickness, such as 100-3,000 micrometers. In one embodiment, the glass core 302 has a thickness of about 1,040 micrometers.

The glass core 302 and substrate 102 may have any suitable length or width, such as 5-500 millimeters. The cavity in the glass core 302 in which the inductor 104 is positioned may have any suitable width, such as 300-1,500 micrometers. In some embodiments, several inductors 104, such as 1-10 rows of 1-10 inductors 104 each, may be positioned in a single cavity of the glass core 302. In such embodiments, the cavity of the glass core 302 will be big enough to fit all of the inductors, such as a cavity width of up to 5,000 micrometers. In some embodiments, any two or more inductors 104 in the glass core 302 may be connected in series or parallel. For example, as shown in FIG. 5, in one embodiment, the inductors 104 may be connected in series, as shown in FIG. 5.

In an illustrative embodiment, a thin buffer layer 304 surrounds the glass core 302. The thin liner layer 304 may be, e.g., parylene C. The liner layer 304 may have any suitable thickness, such as 2-20 micrometers. In an illustrative embodiment, the liner layer 304 has a thickness of about micrometers.

The buffer layer 306 may be any suitable buffer layer that can accommodate small movement between the glass core 203 and the inductor 104 due to, e.g., thermal expansion. The buffer layer 306 may be an organic material, such as a polymer, epoxy resin, etc. In some embodiments, the buffer layer 306 may be embodied as Ajinomoto build-up film (ABF)®. The buffer layer 306 may have any suitable thickness above the glass core 302, such as 30-200 micrometers. In an illustrative embodiment, the buffer layer 306 has a thickness above the glass core 302 of about 65 micrometers. Of course, the buffer layer 306 may be thicker in the area around the inductor 104, such as the entire thickness of the glass core 302 plus 30-200 micrometers.

The buffer layer 306 may have any suitable width between the glass core 302 and the inductor 104, such as 75 micrometers. That is, in one embodiment, the edge of the inductor 104 is about 75 micrometers away from the edge of the glass core 302. In other embodiments, the edge of the inductor 104 may be any suitable distance away from the edge of the glass core, such as 30-300 micrometers.

In an illustrative embodiment, the conductive via 310, the pads 106, the pads 110, 314, the vias 312, 316, other traces and vias on the substrate 102, etc., are copper. Additionally or alternatively, in other embodiments, a different conductive material may be used, such as aluminum, gold, silver, polysilicon, etc. In an illustrative embodiment, the conductive via 310 may have an outer diameter of about 150 micrometers. In other embodiments, the conductive via 310 may have any suitable outer diameter, such as 50-500 micrometers. The illustrative conductive via 310 has a thickness (i.e., the difference between inner and outer radius) of about 25 micrometers. In other embodiments, the conductive via 310 may have a thickness of 10-100 micrometers. The illustrative conductive via 310 has a height that is about 30 micrometers more than the height between the top surface 112 and the bottom surface 114. In other embodiments, the conductive via 310 may have a height that is about the same as the height between the top surface 112 and the bottom surface 114 or, e.g., 0-100 micrometers more or less than the height between the top surface 112 and the bottom surface 114.

The plug 308 may be made of any suitable material, such as an epoxy with spherical glass filler. In one embodiment, the plug 308 may be Taiyo® THP-100DX1 via fill. The plug 308 may be conductive or non-conductive.

The illustrative pad 318 has a diameter of about 350 micrometers and a thickness of about 50 micrometers. In other embodiments, the pad 318 may have a diameter of 200-600 micrometers and a thickness of 15-100 micrometers.

The inductor 104 may have any suitable width, such as a width of 450 micrometers as measured across the magnetic material 108. In other embodiments, the inductor 104 may have a width of, e.g., 200-1,000 micrometers. The magnetic material 108 may be any suitable magnetic material. The magnetic material 108 may include magnetic particles, a binder, and additives. The magnetic particles may be, e.g., iron, nickel, iron alloys, nickel alloys, ferrites such as manganese-zinc ferrites or nickel-zinc ferrites, or magnetic nanoparticles. The binders may hold the magnetic particles in suspension and help adhere the particles to the buffer layer 306 and/or the conductive via 310. In one embodiment, the magnetic material is an Aftinnova® magnetic paste (AMP) from Ajinomoto®, such as AMP PC6. In embodiments with more than one inductor 104 in a single cavity, the inductors 104 may have any suitable pitch, such as 300-800 micrometers. The inductor 104 may have any suitable inductance, such as 1-100 nH.

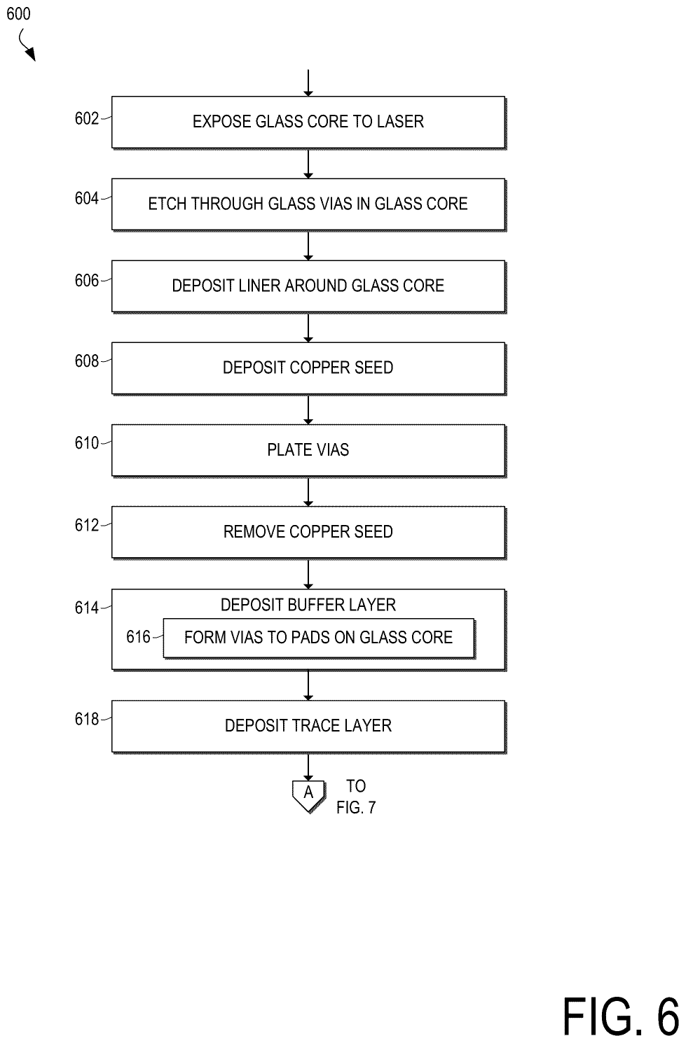

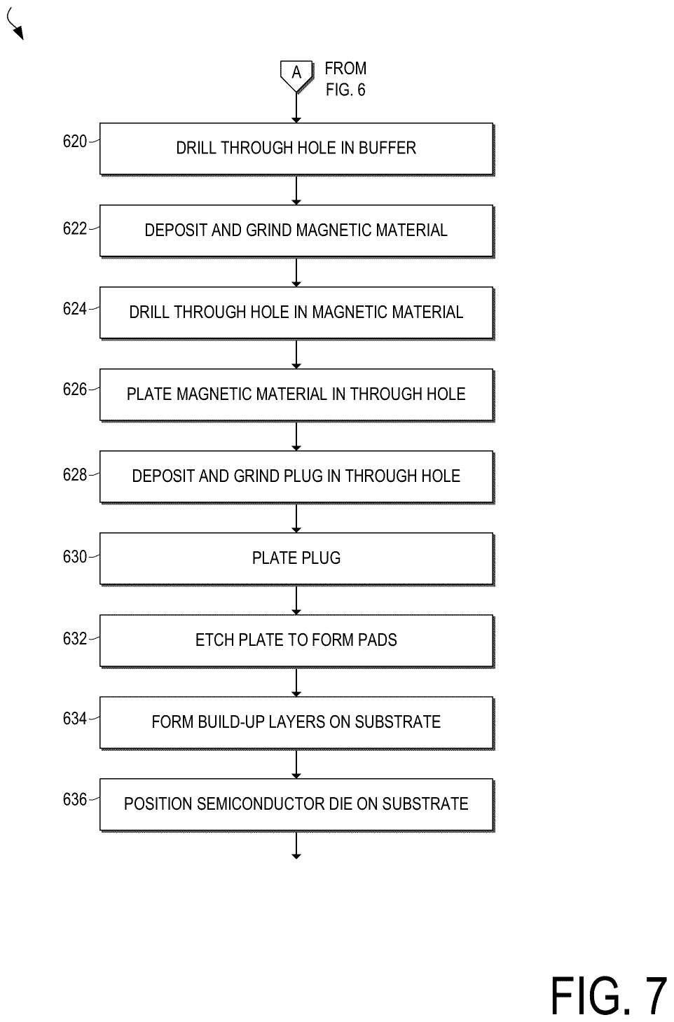

In an illustrative embodiment, the substrate 102 has a buried pad 314 below a top surface 112, and the pad 106 is higher than the pads 110, as a result of a manufacturing process (described below in more detail in regard to FIGS. 6 and 7). In other embodiments, the substrate 102 may not have a buried pad 314 and/or the pads 106 may be even with or lower than the pads 110.

The pads 110, 314 may have any suitable diameter, such as 110 micrometers. In some embodiments, the pads 110, 314 have a diameter of 50-200 micrometers. The pads 110, 314 may have any suitable height, such as 35 micrometers. In some embodiments, the pads 110, 314 may have a height of, e.g., 10-70 micrometers. The pads 110 may have a pitch of 155 micrometers. In other embodiments, the pads 110 may have a pitch of 25-500 micrometers.

The vias 312 may have any suitable width, such as a minimum width of 61.8 micrometers and a maximum width of 80 micrometers. In general, the vias 312 may have a width of 30-200 micrometers.

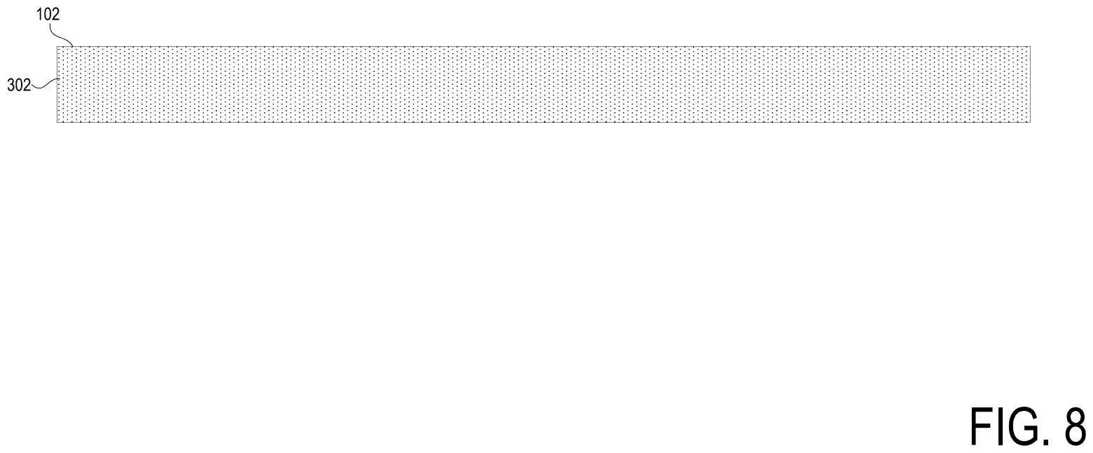

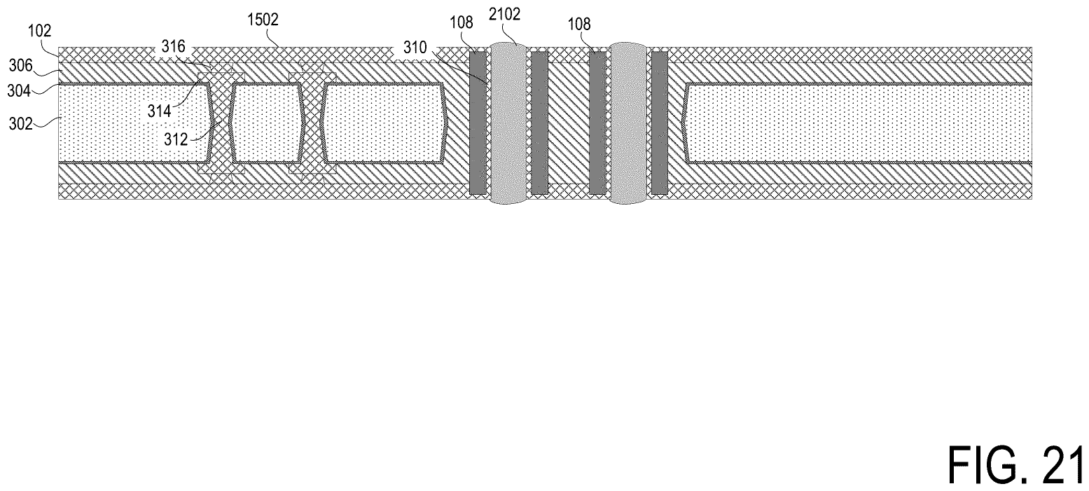

Referring now to FIGS. 6 and 7, in one embodiment, a flowchart for a method 600 for creating the system 100 is shown. The method 600 may be executed by a technician and/or by one or more automated machines. In some embodiments, one or more machines may be programmed to do some or all of the steps of the method 600. Such a machine may include, e.g., a memory, a processor, data storage, etc. The memory and/or data storage may store instructions that, when executed by the machine, cause the machine to perform some or all of the steps of the method 600. The method 600 may use any suitable set of techniques that are used in integrated circuit or semiconductor processing, such as chemical vapor deposition, atomic layer deposition, physical layer deposition, molecular beam epitaxy, layer transfer, photolithography, ion implantation, dry etching, wet etching, thermal treatments, flip chip, layer transfer, magnetron sputter deposition, pulsed laser deposition, laser-induced deep etching (LIDE), selective laser etching, etc. It should be appreciated that the method 600 is merely one embodiment of a method to create the system 100, and other methods may be used to create the system 100. In some embodiments, steps of the method 600 may be performed in a different order than that shown in the flowchart. In some embodiments, different steps or sets of steps may be performed at different locations and/or by different personnel or organizations. FIGS. 8-23 show cross-sectional views of the glass substrate 102 at various steps of the method 600.

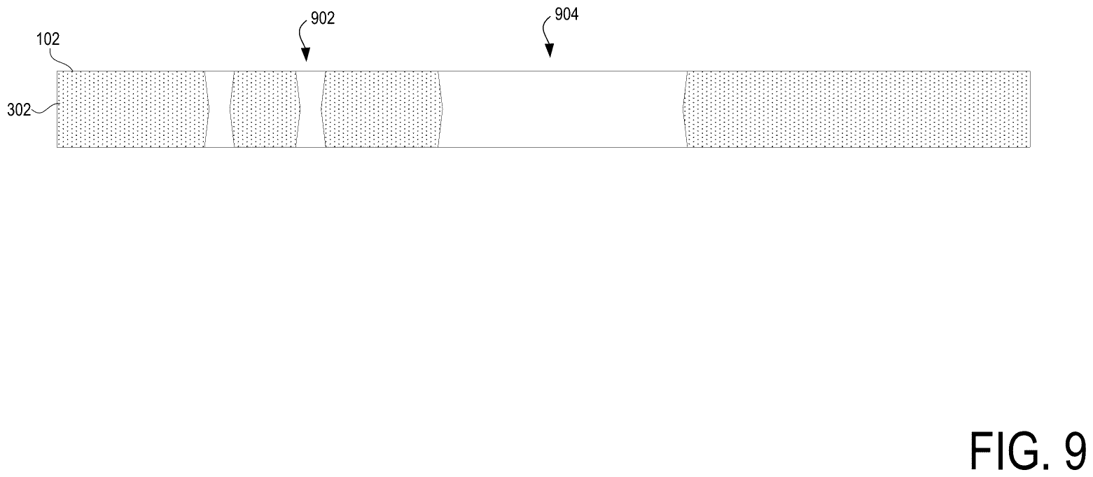

The method 600 beings in block 602, in which a blank glass core 302, as shown in FIG. 8, is exposed is exposed to a laser beam as part of a laser-induced deep etching (LIDE) process. As the glass substrate is exposed to the laser beam, the laser beam alters the structure of the exposed part of glass core 302. In block 604, the through glass vias 902 and the cavity 904 in the glass core 302 are etched by etching away the part of the glass core 302 exposed to the laser, as shown in FIG. 9. The exposed regions may be etched in any suitable manner, such as by using wet chemical etching with, e.g., hydrofluoric acid.

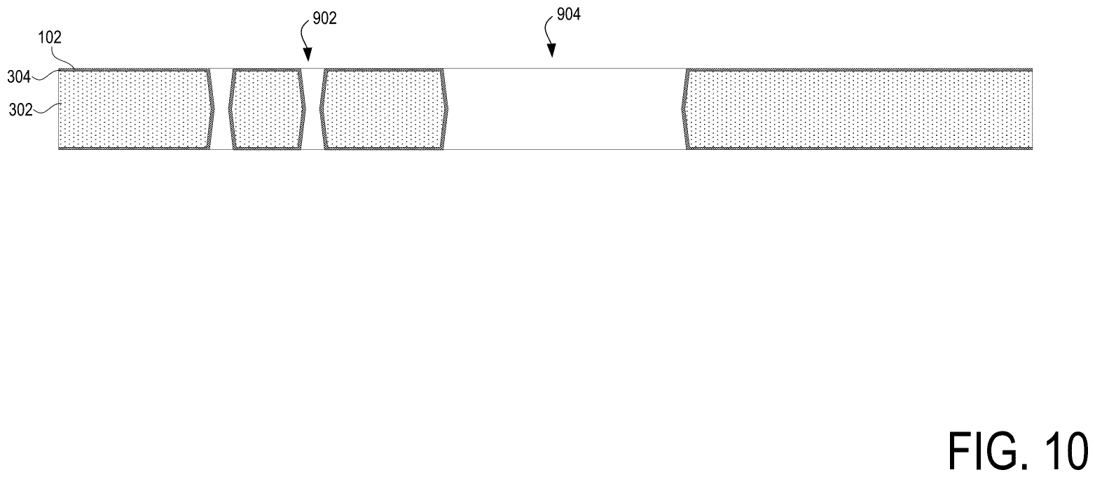

In block 606, a liner 304 is deposited around the glass core 302, as shown in FIG. 10. The liner 304 may be propylene C. The liner 304 can help protect the glass core 302 from, e.g., stresses due to changes in the size of various components due to changes in temperature.

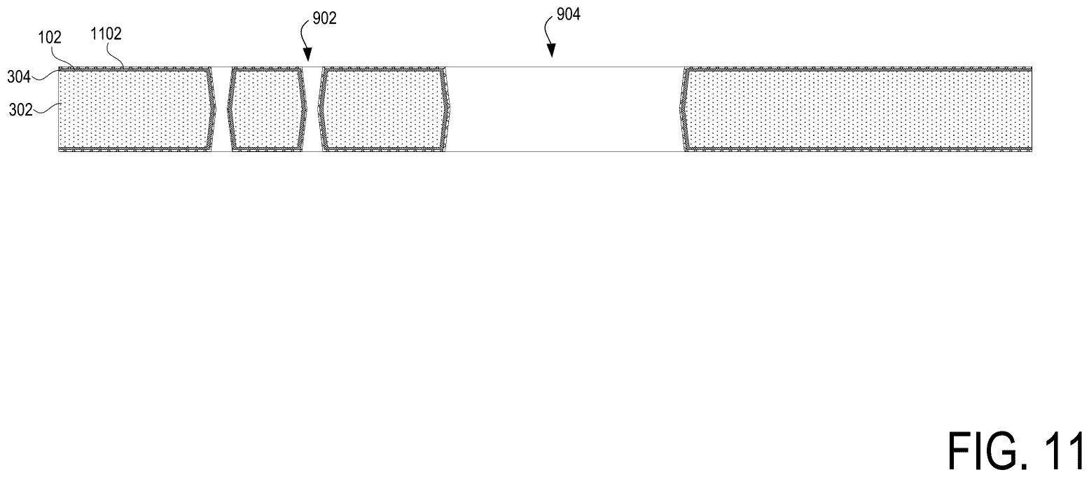

In block 608, a copper seed 1102 is deposited around the liner 304, as shown in FIG. 11. The copper seed 1102 may be deposited in any suitable manner, such as by using electroless plating.

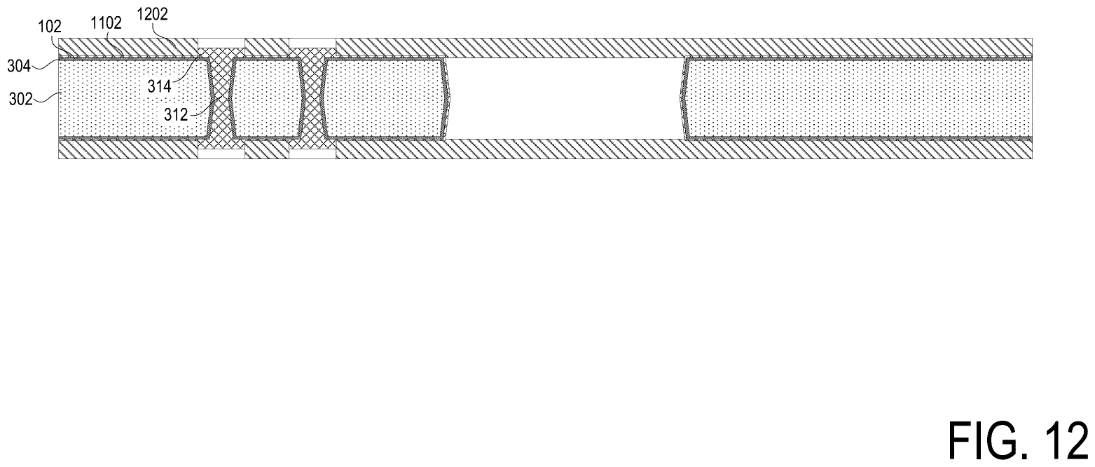

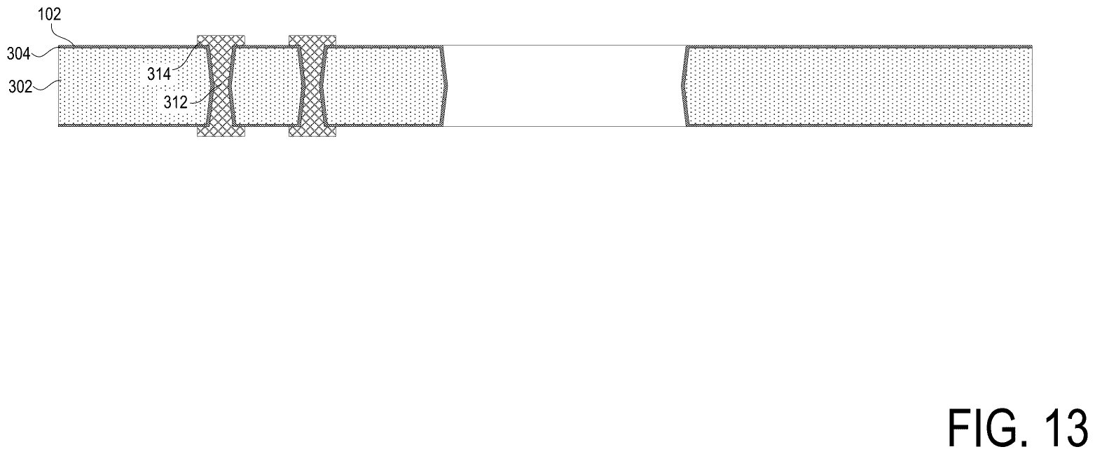

In block 610, the vias 312 and pads 314 are plated, as shown in FIG. 12. A mask 1202 may be deposited to block portions of the substrate 102 that should not be plated. The mask 1202 and the copper seed 1102 are removed in block 612, as shown in FIG. 13.

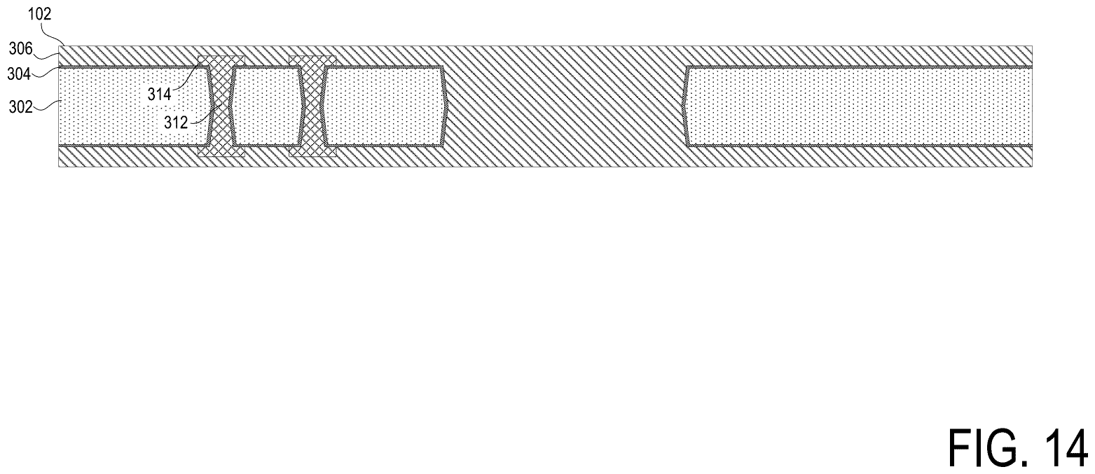

In block 614, the buffer layer 306 is deposited, as shown in FIG. 14. In an illustrative embodiment, the buffer layer 306 may be Ajinomoto build-up film (ABF)®. In block 616, vias 316 are formed through the buffer layer 306 to connect to the pads 314.

In block 618, a trace layer 1502 is deposited on the buffer layer 306. The trace layer 1502 may be deposited by, e.g., electroless plating of a copper seed on the buffer layer 306 and electroplating the copper seed layer.

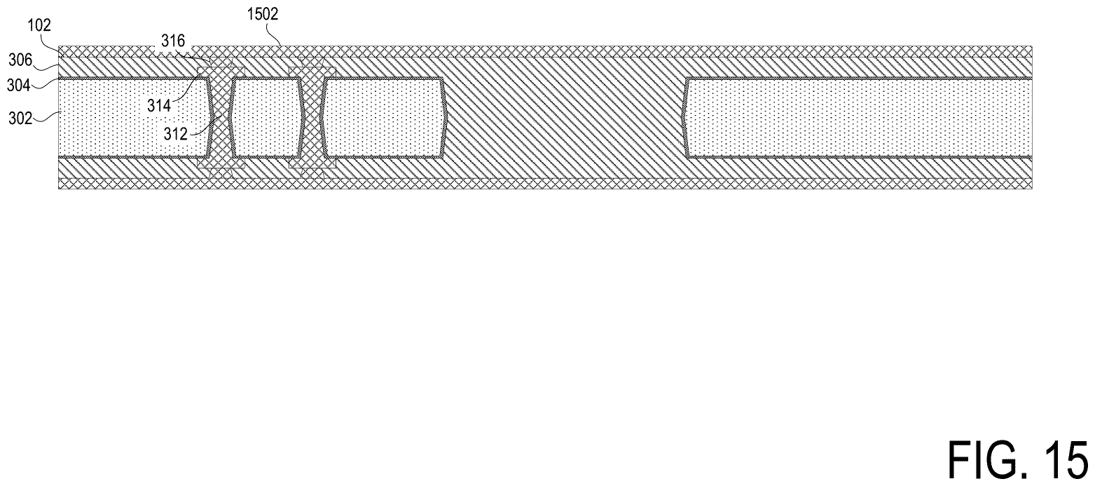

In one embodiment, some or all of the steps 602-618 may be performed at one location by one set of personnel, equipment, or organization, and then the substrate 102, as shown in FIG. 15, may be sent to another organization, such as a substrate supplier, for additional processing, such as some or all of steps 620-634 shown in FIG. 7. In other embodiments, all or any combination of steps 602-634 may be performed by one or more sets of personnel, equipment, or organizations.

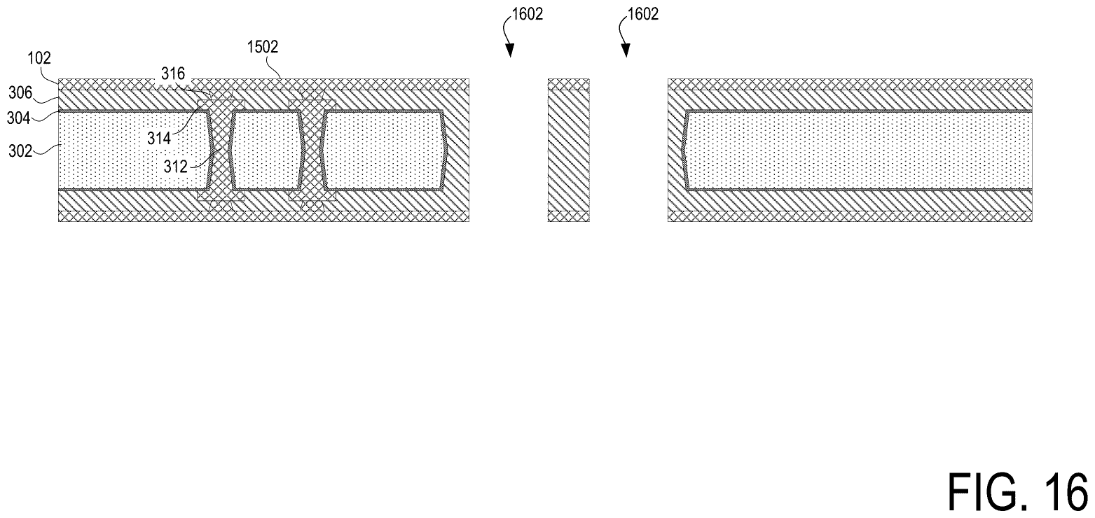

Referring now to FIG. 7, in block 620, through holes 1602 are drilled through the substrate 102, as shown in FIG. 16. In one embodiment, the through holes 1602 are mechanically drilled through the substrate 102. In other embodiments, the through holes 1602 may be laser drilled or chemically etched.

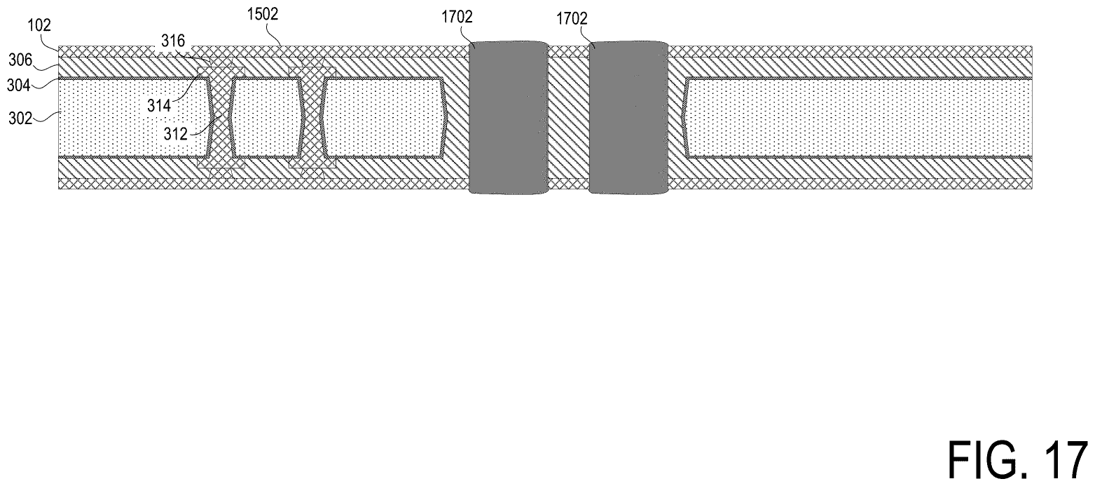

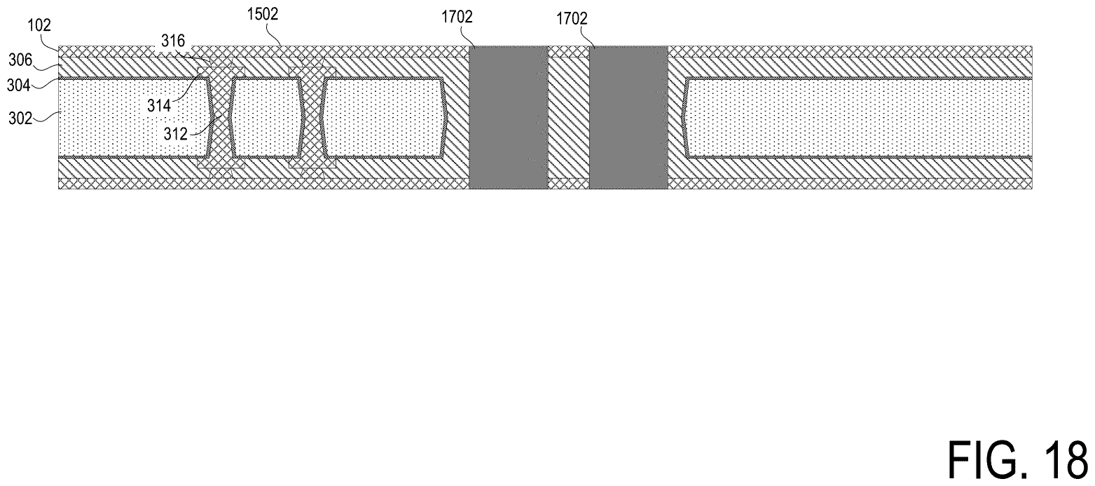

In block 622, a magnetic material 1702 is deposited in the through holes 1602, as shown in FIG. 17. The magnetic material 1702 is ground down to the plane of the trace layer 1502, as shown in FIG. 18.

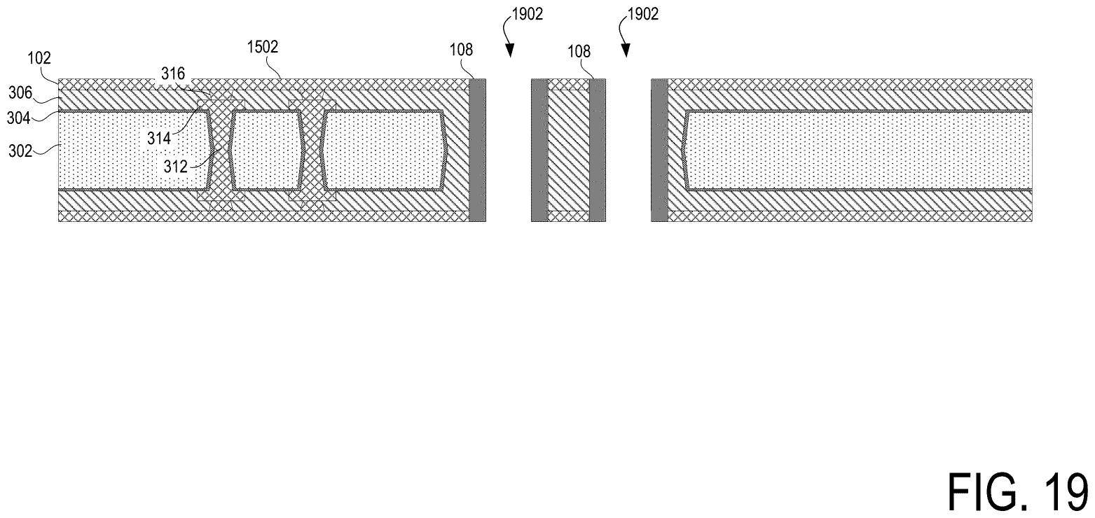

In block 624, through holes 1902 are drilled through the substrate 102, as shown in FIG. 19, forming the coaxial magnetic material 108 that will surround the via 310. The through holes 1902 may be formed in a similar manner as the through holes 1602.

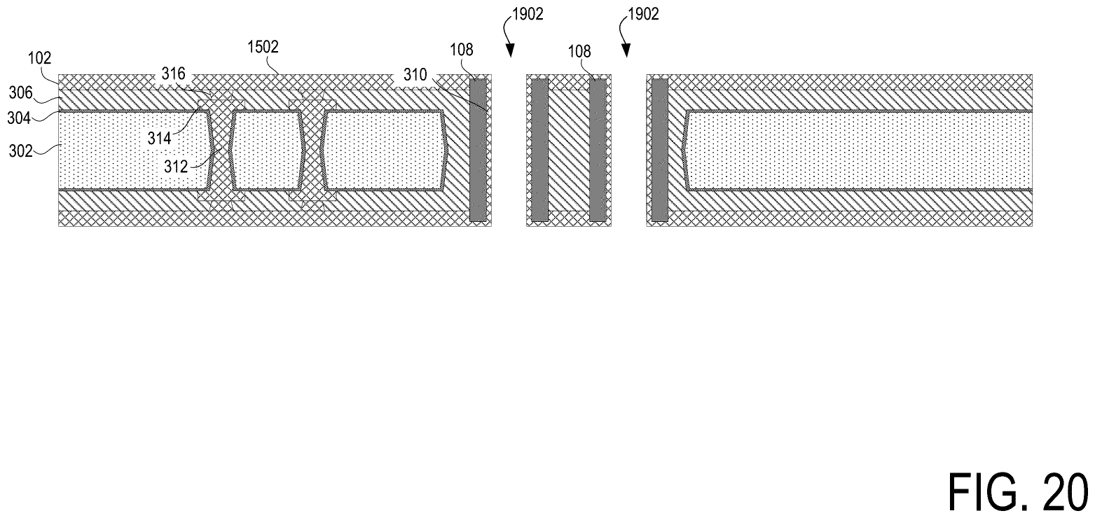

In block 626, the vias 310 are plated on the magnetic material 108, as shown in FIG. 20. In some embodiments, the trace layer 1502 may be plated as well, getting slightly thicker.

In block 628, the plug material 2102 is deposited in the through holes 1902, as shown in FIG. 20. The plug material 2102 can be ground to be flush with the trace layer 1502 to form the plug 308.

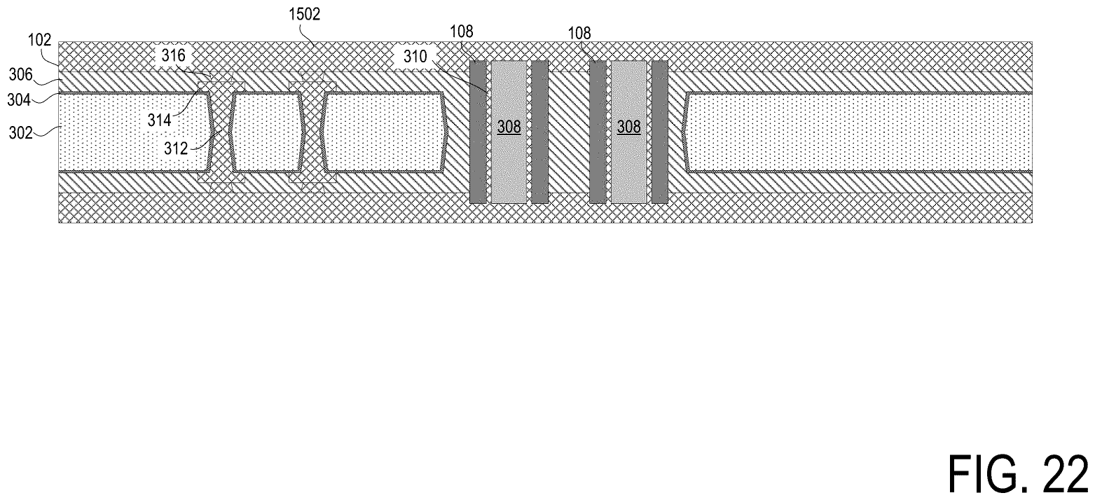

In block 630, the plug 308 may be plated, as shown in FIG. 22. In an illustrative embodiment, the trace layer 1502 grows to the height of the pads 106. In block 632, the trace layer 1502 is etched, forming pads 106, 110. At this point, the substrate 102 appears as it does in FIG. 3.

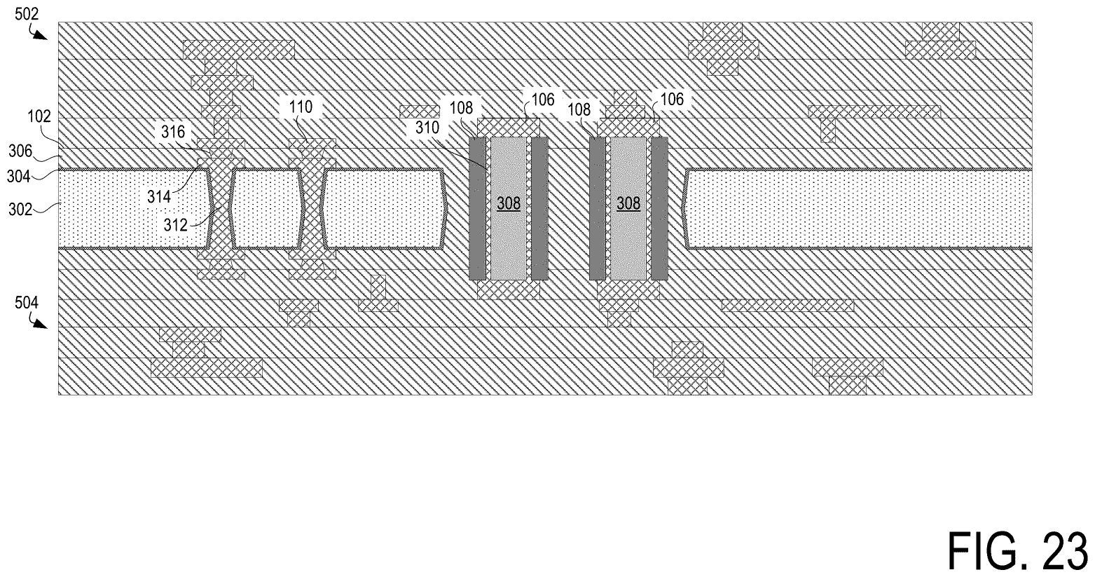

In block 634, build-up layers 502, 504 are added on top and on bottom of the substrate 102, as shown in FIG. 23. As part of adding the build-up layers 502, 504, in some embodiments, some or all of the components of a FIVR may be connected to the inductor 104. In block 636, one or more semiconductor dies 506 are positioned on top of the build-up layer 502. At this point, the system 500 appears as it does in FIG. 5.

It should be appreciated that the method 600 described above results in the pad 106 being at a different height than the pad 110. In some embodiments, a different method may be used to form the pads 106, 110 at the same height. In the method 600 described above, the buried pad 314 is formed as part of forming the inductor 104 in the cavity 904. In some embodiments, the buried pad 314 may not have any connections to it other than the vias 312, 316. In other embodiments, a different method may be used that will not result in such a buried pad 314.

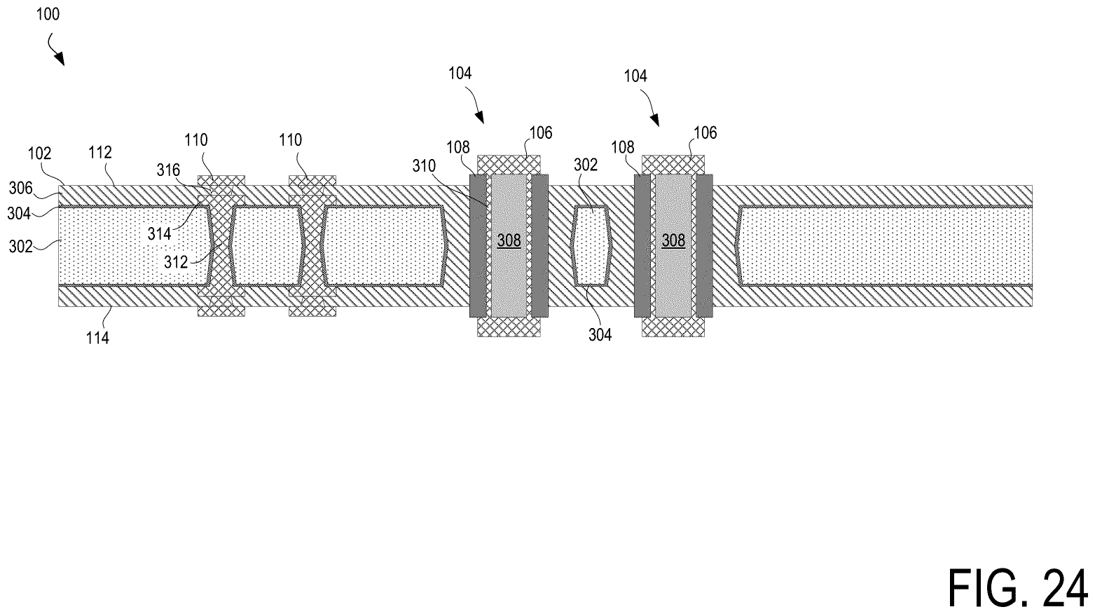

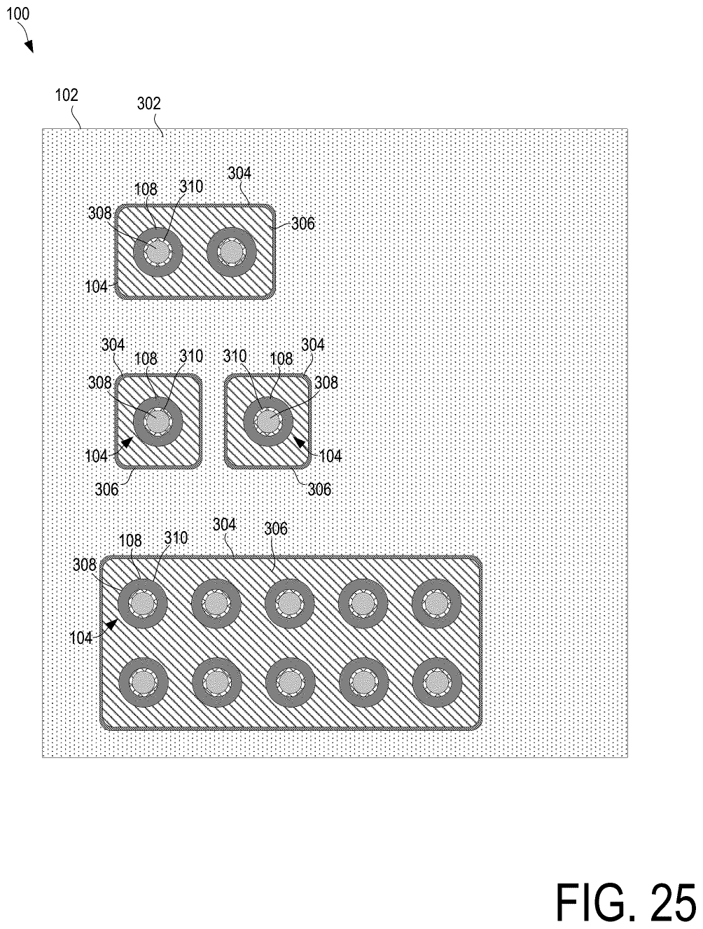

It should be appreciated that the embodiments shown in FIGS. 1-4 are merely one possible embodiment of the inductor 104 and that additional variations are envisioned. For example, in some embodiments, a substrate 102 may include inductors 104 in separate cavities of the glass core 302, as shown in FIG. 24. The minimum pitch between inductors 104 in separate cavities of the glass core 302 may be any suitable value, such as 600-1,000 micrometers. In one embodiment, a minimum pitch between inductors 104 may be 700 micrometers. Additionally or alternatively, a substrate 102 may include any suitable combination of inductors 104 in any suitable combination of cavities in the glass core 302. For example, as shown in FIG. 25, a substrate may include a 2×1 array of inductors 104, 1×1 arrays of inductors 104, a 2×5 array of inductors 104, and/or the like.

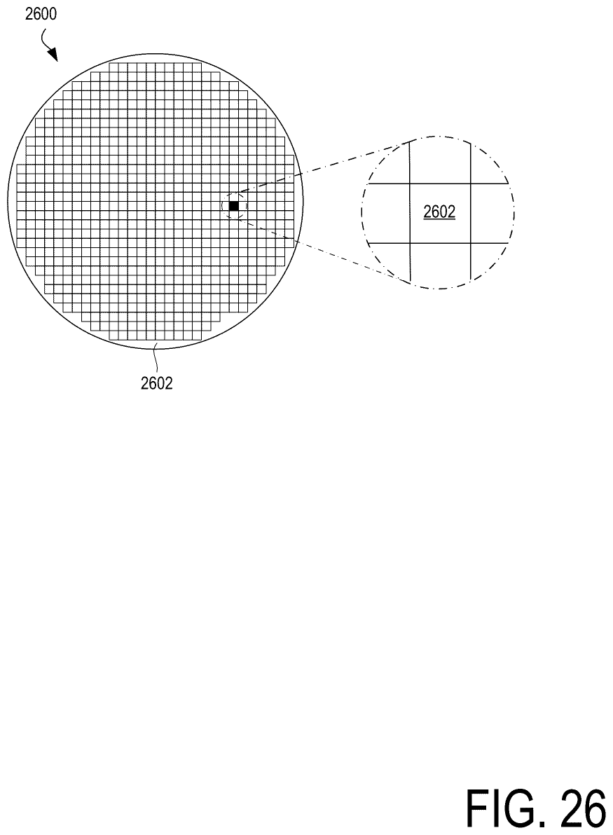

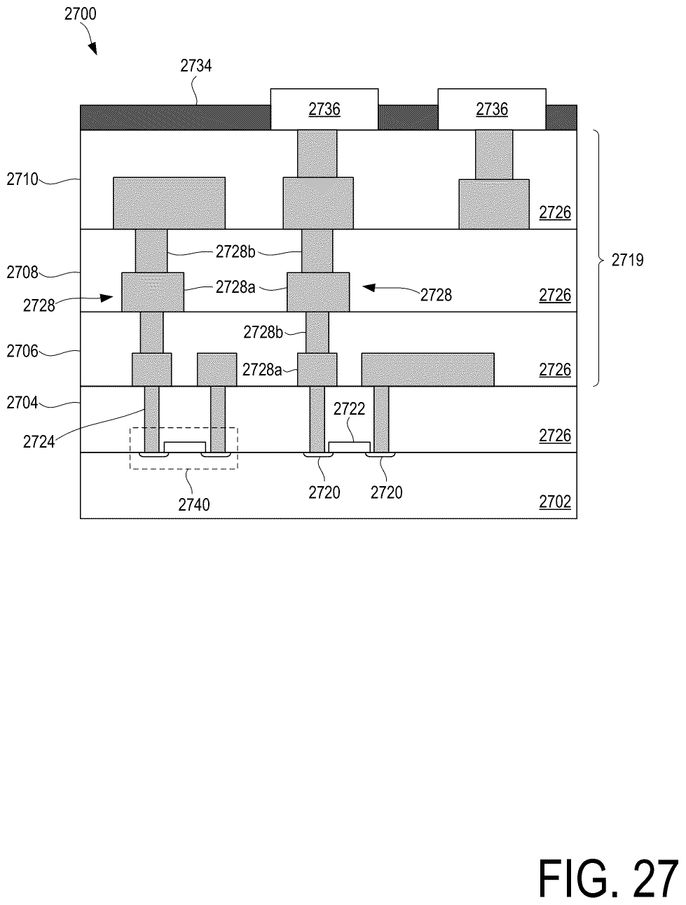

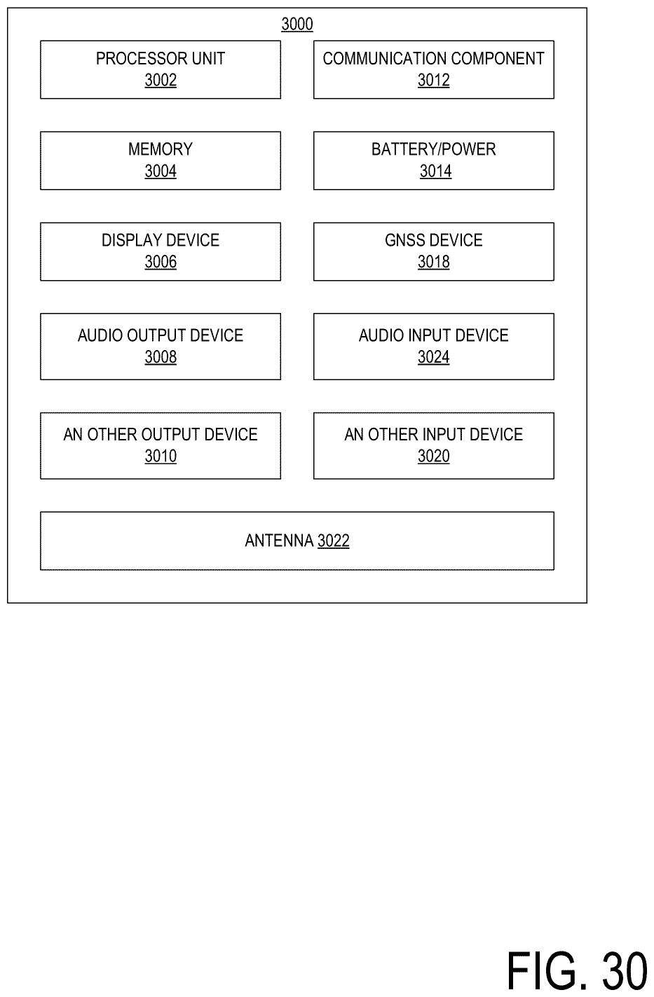

FIG. 26 is a top view of a wafer 2600 and dies 2602 that may be included in any of the systems 100 disclosed herein (e.g., as any suitable ones of the dies 506). The wafer 2600 may be composed of semiconductor material and may include one or more dies 2602 having integrated circuit structures formed on a surface of the wafer 2600. The individual dies 2602 may be a repeating unit of an integrated circuit product that includes any suitable integrated circuit. After the fabrication of the semiconductor product is complete, the wafer 2600 may undergo a singulation process in which the dies 2602 are separated from one another to provide discrete “chips” of the integrated circuit product. The die 2602 may be any of the dies 506 disclosed herein. The die 2602 may include one or more transistors (e.g., some of the transistors 2740 of FIG. 27, discussed below), supporting circuitry to route electrical signals to the transistors, passive components (e.g., signal traces, resistors, capacitors, or inductors), and/or any other integrated circuit components. In some embodiments, the wafer 2600 or the die 2602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 2602. For example, a memory array formed by multiple memory devices may be formed on a same die 2602 as a processor unit (e.g., the processor unit 3002 of FIG. 30) or other logic that is configured to store information in the memory devices or execute instructions stored in the memory array. Various ones of the systems 100 disclosed herein may be manufactured using a die-to-wafer assembly technique in which some dies 506 are attached to a wafer 2600 that include others of the dies 506, and the wafer 2600 is subsequently singulated.

FIG. 27 is a cross-sectional side view of an integrated circuit device 2700 that may be included in any of the systems 100 disclosed herein (e.g., in any of the dies 506). One or more of the integrated circuit devices 2700 may be included in one or more dies 2602 (FIG. 26). The integrated circuit device 2700 may be formed on a die substrate 2702 (e.g., the wafer 2600 of FIG. 26) and may be included in a die (e.g., the die 2602 of FIG. 26). The die substrate 2702 may be a semiconductor substrate composed of semiconductor material systems including, for example, n-type or p-type materials systems (or a combination of both). The die substrate 2702 may include, for example, a crystalline substrate formed using a bulk silicon or a silicon-on-insulator (SOI) substructure. In some embodiments, the die substrate 2702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 2702. Although a few examples of materials from which the die substrate 2702 may be formed are described here, any material that may serve as a foundation for an integrated circuit device 2700 may be used. The die substrate 2702 may be part of a singulated die (e.g., the dies 2602 of FIG. 26) or a wafer (e.g., the wafer 2600 of FIG. 26).

The integrated circuit device 2700 may include one or more device layers 2704 disposed on the die substrate 2702. The device layer 2704 may include features of one or more transistors 2740 (e.g., metal oxide semiconductor field-effect transistors (MOSFETs)) formed on the die substrate 2702. The transistors 2740 may include, for example, one or more source and/or drain (S/D) regions 2720, a gate 2722 to control current flow between the S/D regions 2720, and one or more S/D contacts 2724 to route electrical signals to/from the S/D regions 2720. The transistors 2740 may include additional features not depicted for the sake of clarity, such as device isolation regions, gate contacts, and the like. The transistors 2740 are not limited to the type and configuration depicted in FIG. 27 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

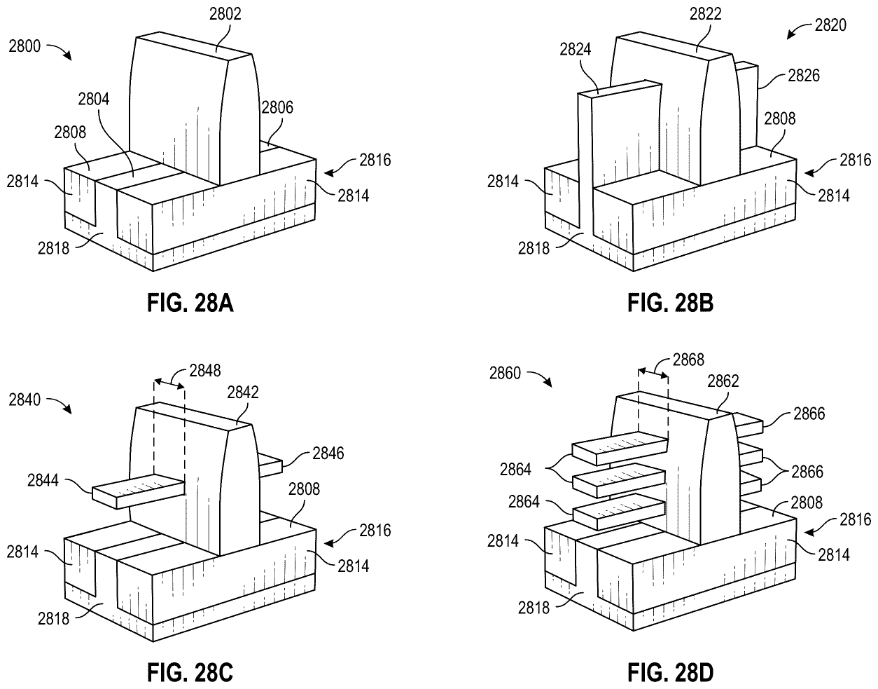

FIGS. 28A-28D are simplified perspective views of example planar, FinFET, gate-all-around, and stacked gate-all-around transistors. The transistors illustrated in FIGS. 28A-28D are formed on a substrate 2816 having a surface 2808. Isolation regions 2814 separate the source and drain regions of the transistors from other transistors and from a bulk region 2818 of the substrate 2816.

FIG. 28A is a perspective view of an example planar transistor 2800 comprising a gate 2802 that controls current flow between a source region 2804 and a drain region 2806. The transistor 2800 is planar in that the source region 2804 and the drain region 2806 are planar with respect to the substrate surface 2808.

FIG. 28B is a perspective view of an example FinFET transistor 2820 comprising a gate 2822 that controls current flow between a source region 2824 and a drain region 2826. The transistor 2820 is non-planar in that the source region 2824 and the drain region 2826 comprise “fins” that extend upwards from the substrate surface 2828. As the gate 2822 encompasses three sides of the semiconductor fin that extends from the source region 2824 to the drain region 2826, the transistor 2820 can be considered a tri-gate transistor. FIG. 28B illustrates one S/D fin extending through the gate 2822, but multiple S/D fins can extend through the gate of a FinFET transistor.

FIG. 28C is a perspective view of a gate-all-around (GAA) transistor 2840 comprising a gate 2842 that controls current flow between a source region 2844 and a drain region 2846. The transistor 2840 is non-planar in that the source region 2844 and the drain region 2846 are elevated from the substrate surface 2828.

FIG. 28D is a perspective view of a GAA transistor 2860 comprising a gate 2862 that controls current flow between multiple elevated source regions 2864 and multiple elevated drain regions 2866. The transistor 2860 is a stacked GAA transistor as the gate controls the flow of current between multiple elevated S/D regions stacked on top of each other. The transistors 2840 and 2860 are considered gate-all-around transistors as the gates encompass all sides of the semiconductor portions that extends from the source regions to the drain regions. The transistors 2840 and 2860 can alternatively be referred to as nanowire, nanosheet, or nanoribbon transistors depending on the width (e.g., widths 2848 and 2868 of transistors 2840 and 2860, respectively) of the semiconductor portions extending through the gate.

Returning to FIG. 27, a transistor 2740 may include a gate 2722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 2740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 2740 along the source-channel-drain direction, the gate electrode may consist of a U-shaped structure that includes a bottom portion substantially parallel to the surface of the die substrate 2702 and two sidewall portions that are substantially perpendicular to the top surface of the die substrate 2702. In other embodiments, at least one of the metal layers that form the gate electrode may simply be a planar layer that is substantially parallel to the top surface of the die substrate 2702 and does not include sidewall portions substantially perpendicular to the top surface of the die substrate 2702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 2720 may be formed within the die substrate 2702 adjacent to the gate 2722 of individual transistors 2740. The S/D regions 2720 may be formed using an implantation/diffusion process or an etching/deposition process, for example. In the former process, dopants such as boron, aluminum, antimony, phosphorous, or arsenic may be ion-implanted into the die substrate 2702 to form the S/D regions 2720. An annealing process that activates the dopants and causes them to diffuse farther into the die substrate 2702 may follow the ion-implantation process. In the latter process, the die substrate 2702 may first be etched to form recesses at the locations of the S/D regions 2720. An epitaxial deposition process may then be carried out to fill the recesses with material that is used to fabricate the S/D regions 2720. In some implementations, the S/D regions 2720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 2720 may be formed using one or more alternate semiconductor materials such as germanium or a group III-V material or alloy. In further embodiments, one or more layers of metal and/or metal alloys may be used to form the S/D regions 2720.

Electrical signals, such as power and/or input/output (I/O) signals, may be routed to and/or from the devices (e.g., transistors 2740) of the device layer 2704 through one or more interconnect layers disposed on the device layer 2704 (illustrated in FIG. 27 as interconnect layers 2706-2710). For example, electrically conductive features of the device layer 2704 (e.g., the gate 2722 and the S/D contacts 2724) may be electrically coupled with the interconnect structures 2728 of the interconnect layers 2706-2710. The one or more interconnect layers 2706-2710 may form a metallization stack (also referred to as an “ILD stack”) 2719 of the integrated circuit device 2700.

The interconnect structures 2728 may be arranged within the interconnect layers 2706-2710 to route electrical signals according to a wide variety of designs; in particular, the arrangement is not limited to the particular configuration of interconnect structures 2728 depicted in FIG. 27. Although a particular number of interconnect layers 2706-2710 is depicted in FIG. 27, embodiments of the present disclosure include integrated circuit devices having more or fewer interconnect layers than depicted.

In some embodiments, the interconnect structures 2728 may include lines 2728a and/or vias 2728b filled with an electrically conductive material such as a metal. The lines 2728a may be arranged to route electrical signals in a direction of a plane that is substantially parallel with a surface of the die substrate 2702 upon which the device layer 2704 is formed. For example, the lines 2728a may route electrical signals in a direction in and out of the page and/or in a direction across the page. The vias 2728b may be arranged to route electrical signals in a direction of a plane that is substantially perpendicular to the surface of the die substrate 2702 upon which the device layer 2704 is formed. In some embodiments, the vias 2728b may electrically couple lines 2728a of different interconnect layers 2706-2710 together.

The interconnect layers 2706-2710 may include a dielectric material 2726 disposed between the interconnect structures 2728, as shown in FIG. 27. In some embodiments, dielectric material 2726 disposed between the interconnect structures 2728 in different ones of the interconnect layers 2706-2710 may have different compositions; in other embodiments, the composition of the dielectric material 2726 between different interconnect layers 2706-2710 may be the same. The device layer 2704 may include a dielectric material 2726 disposed between the transistors 2740 and a bottom layer of the metallization stack as well. The dielectric material 2726 included in the device layer 2704 may have a different composition than the dielectric material 2726 included in the interconnect layers 2706-2710; in other embodiments, the composition of the dielectric material 2726 in the device layer 2704 may be the same as a dielectric material 2726 included in any one of the interconnect layers 2706-2710.

A first interconnect layer 2706 (referred to as Metal 1 or “M1”) may be formed directly on the device layer 2704. In some embodiments, the first interconnect layer 2706 may include lines 2728a and/or vias 2728b, as shown. The lines 2728a of the first interconnect layer 2706 may be coupled with contacts (e.g., the S/D contacts 2724) of the device layer 2704. The vias 2728b of the first interconnect layer 2706 may be coupled with the lines 2728a of a second interconnect layer 2708.

The second interconnect layer 2708 (referred to as Metal 2 or “M2”) may be formed directly on the first interconnect layer 2706. In some embodiments, the second interconnect layer 2708 may include via 2728b to couple the lines 2728 of the second interconnect layer 2708 with the lines 2728a of a third interconnect layer 2710. Although the lines 2728a and the vias 2728b are structurally delineated with a line within individual interconnect layers for the sake of clarity, the lines 2728a and the vias 2728b may be structurally and/or materially contiguous (e.g., simultaneously filled during a dual-damascene process) in some embodiments.

The third interconnect layer 2710 (referred to as Metal 3 or “M3”) (and additional interconnect layers, as desired) may be formed in succession on the second interconnect layer 2708 according to similar techniques and configurations described in connection with the second interconnect layer 2708 or the first interconnect layer 2706. In some embodiments, the interconnect layers that are “higher up” in the metallization stack 2719 in the integrated circuit device 2700 (i.e., farther away from the device layer 2704) may be thicker that the interconnect layers that are lower in the metallization stack 2719, with lines 2728a and vias 2728b in the higher interconnect layers being thicker than those in the lower interconnect layers.

The integrated circuit device 2700 may include a solder resist material 2734 (e.g., polyimide or similar material) and one or more conductive contacts 2736 formed on the interconnect layers 2706-2710. In FIG. 27, the conductive contacts 2736 are illustrated as taking the form of bond pads. The conductive contacts 2736 may be electrically coupled with the interconnect structures 2728 and configured to route the electrical signals of the transistor(s) 2740 to external devices. For example, solder bonds may be formed on the one or more conductive contacts 2736 to mechanically and/or electrically couple an integrated circuit die including the integrated circuit device 2700 with another component (e.g., a printed circuit board). The integrated circuit device 2700 may include additional or alternate structures to route the electrical signals from the interconnect layers 2706-2710; for example, the conductive contacts 2736 may include other analogous features (e.g., posts) that route the electrical signals to external components. The conductive contacts 2736 may serve as the conductive contacts 106, 110, as appropriate.

In some embodiments in which the integrated circuit device 2700 is a double-sided die, the integrated circuit device 2700 may include another metallization stack (not shown) on the opposite side of the device layer(s) 2704. This metallization stack may include multiple interconnect layers as discussed above with reference to the interconnect layers 2706-2710, to provide conductive pathways (e.g., including conductive lines and vias) between the device layer(s) 2704 and additional conductive contacts (not shown) on the opposite side of the integrated circuit device 2700 from the conductive contacts 2736. These additional conductive contacts may serve as the conductive contacts 110 or 106, as appropriate.

In other embodiments in which the integrated circuit device 2700 is a double-sided die, the integrated circuit device 2700 may include one or more through silicon vias (TSVs) through the die substrate 2702; these TSVs may make contact with the device layer(s) 2704, and may provide conductive pathways between the device layer(s) 2704 and additional conductive contacts (not shown) on the opposite side of the integrated circuit device 2700 from the conductive contacts 2736. These additional conductive contacts may serve as the conductive contacts 110 or 106, as appropriate. In some embodiments, TSVs extending through the substrate can be used for routing power and ground signals from conductive contacts on the opposite side of the integrated circuit device 2700 from the conductive contacts 2736 to the transistors 2740 and any other components integrated into the die 2700, and the metallization stack 2719 can be used to route I/O signals from the conductive contacts 2736 to transistors 2740 and any other components integrated into the die 2700.

Multiple integrated circuit devices 2700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

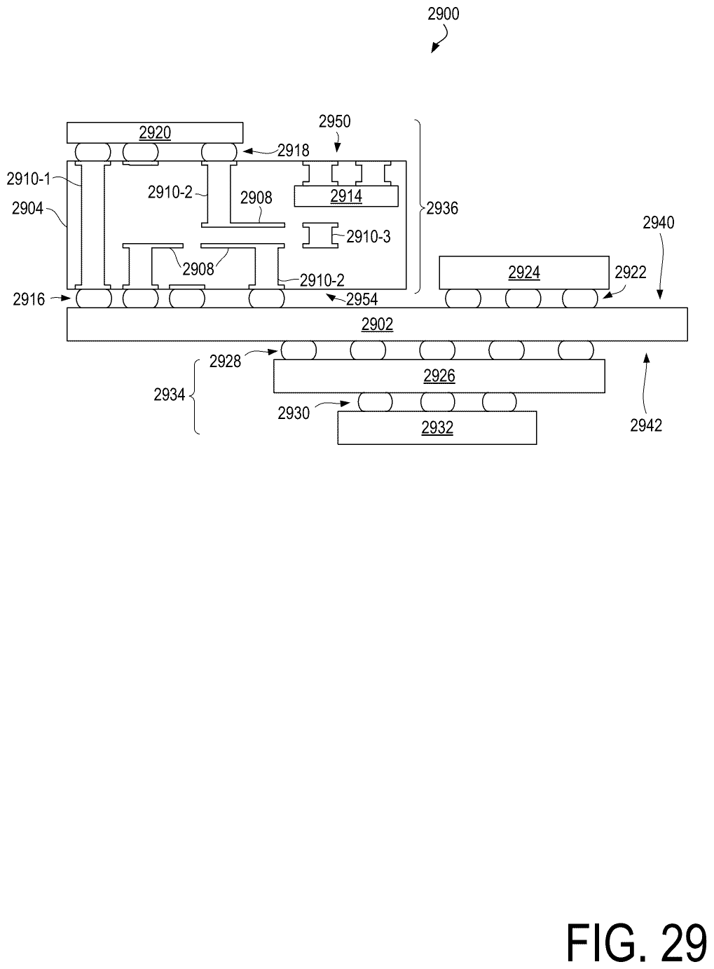

FIG. 29 is a cross-sectional side view of an integrated circuit device assembly 2900 that may include any of the systems 100 disclosed herein. In some embodiments, the integrated circuit device assembly 2900 may include a substate 102. The integrated circuit device assembly 2900 includes a number of components disposed on a circuit board 2902 (which may be a motherboard, system board, mainboard, etc.). The integrated circuit device assembly 2900 includes components disposed on a first face 2940 of the circuit board 2902 and an opposing second face 2942 of the circuit board 2902; generally, components may be disposed on one or both faces 2940 and 2942. Any of the integrated circuit components discussed below with reference to the integrated circuit device assembly 2900 may take the form of any suitable ones of the embodiments of the system 100 disclosed herein.

In some embodiments, the circuit board 2902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 2902. In other embodiments, the circuit board 2902 may be a non-PCB substrate. In some embodiments the circuit board 2902 may be, for example, the substrate 102. The integrated circuit device assembly 2900 illustrated in FIG. 29 includes a package-on-interposer structure 2936 coupled to the first face 2940 of the circuit board 2902 by coupling components 2916. The coupling components 2916 may electrically and mechanically couple the package-on-interposer structure 2936 to the circuit board 2902, and may include solder balls (as shown in FIG. 29), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 2916 may serve as the coupling components illustrated or described for any of the substrate assembly or substrate assembly components described herein, as appropriate.

The package-on-interposer structure 2936 may include an integrated circuit component 2920 coupled to an interposer 2904 by coupling components 2918. The coupling components 2918 may take any suitable form for the application, such as the forms discussed above with reference to the coupling components 2916. Although a single integrated circuit component 2920 is shown in FIG. 29, multiple integrated circuit components may be coupled to the interposer 2904; indeed, additional interposers may be coupled to the interposer 2904. The interposer 2904 may provide an intervening substrate used to bridge the circuit board 2902 and the integrated circuit component 2920.

The integrated circuit component 2920 may be a packaged or unpacked integrated circuit product that includes one or more integrated circuit dies (e.g., the die 2602 of FIG. 26, the integrated circuit device 2700 of FIG. 27) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 2920, a single monolithic integrated circuit die comprises solder bumps attached to contacts on the die. The solder bumps allow the die to be directly attached to the interposer 2904. The integrated circuit component 2920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 2920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 2920 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 2920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 2904 may spread connections to a wider pitch or reroute a connection to a different connection. For example, the interposer 2904 may couple the integrated circuit component 2920 to a set of ball grid array (BGA) conductive contacts of the coupling components 2916 for coupling to the circuit board 2902. In the embodiment illustrated in FIG. 29, the integrated circuit component 2920 and the circuit board 2902 are attached to opposing sides of the interposer 2904; in other embodiments, the integrated circuit component 2920 and the circuit board 2902 may be attached to a same side of the interposer 2904. In some embodiments, three or more components may be interconnected by way of the interposer 2904.

In some embodiments, the interposer 2904 may be formed as a PCB, including multiple metal layers separated from one another by layers of dielectric material and interconnected by electrically conductive vias. In some embodiments, the interposer 2904 may be formed of an epoxy resin, a fiberglass-reinforced epoxy resin, an epoxy resin with inorganic fillers, a ceramic material, or a polymer material such as polyimide. In some embodiments, the interposer 2904 may be formed of alternate rigid or flexible materials that may include the same materials described above for use in a semiconductor substrate, such as silicon, germanium, and other group III-V and group IV materials. The interposer 2904 may include metal interconnects 2908 and vias 2910, including but not limited to through hole vias 2910-1 (that extend from a first face 2950 of the interposer 2904 to a second face 2954 of the interposer 2904), blind vias 2910-2 (that extend from the first or second faces 2950 or 2954 of the interposer 2904 to an internal metal layer), and buried vias 2910-3 (that connect internal metal layers).

In some embodiments, the interposer 2904 can comprise a silicon interposer. Through silicon vias (TSV) extending through the silicon interposer can connect connections on a first face of a silicon interposer to an opposing second face of the silicon interposer. In some embodiments, an interposer 2904 comprising a silicon interposer can further comprise one or more routing layers to route connections on a first face of the interposer 2904 to an opposing second face of the interposer 2904.

The interposer 2904 may further include embedded devices 2914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2904. The package-on-interposer structure 2936 may take the form of any of the package-on-interposer structures known in the art.

The integrated circuit device assembly 2900 may include an integrated circuit component 2924 coupled to the first face 2940 of the circuit board 2902 by coupling components 2922. The coupling components 2922 may take the form of any of the embodiments discussed above with reference to the coupling components 2916, and the integrated circuit component 2924 may take the form of any of the embodiments discussed above with reference to the integrated circuit component 2920.

The integrated circuit device assembly 2900 illustrated in FIG. 29 includes a package-on-package structure 2934 coupled to the second face 2942 of the circuit board 2902 by coupling components 2928. The package-on-package structure 2934 may include an integrated circuit component 2926 and an integrated circuit component 2932 coupled together by coupling components 2930 such that the integrated circuit component 2926 is disposed between the circuit board 2902 and the integrated circuit component 2932. The coupling components 2928 and 2930 may take the form of any of the embodiments of the coupling components 2916 discussed above, and the integrated circuit components 2926 and 2932 may take the form of any of the embodiments of the integrated circuit component 2920 discussed above. The package-on-package structure 2934 may be configured in accordance with any of the package-on-package structures known in the art.

FIG. 30 is a block diagram of an example electrical device 3000 that may include one or more of the systems 100 disclosed herein. For example, any suitable ones of the components of the electrical device 3000 may include one or more of the integrated circuit device assemblies 2900, integrated circuit components 2920, integrated circuit devices 2700, or integrated circuit dies 2602 disclosed herein, and may be arranged in any of the systems 100 disclosed herein. A number of components are illustrated in FIG. 30 as included in the electrical device 3000, but any one or more of these components may be omitted or duplicated, as suitable for the application. In some embodiments, some or all of the components included in the electrical device 3000 may be attached to one or more motherboards mainboards, or system boards. In some embodiments, one or more of these components are fabricated onto a single system-on-a-chip (SoC) die.

Additionally, in various embodiments, the electrical device 3000 may not include one or more of the components illustrated in FIG. 30, but the electrical device 3000 may include interface circuitry for coupling to the one or more components. For example, the electrical device 3000 may not include a display device 3006, but may include display device interface circuitry (e.g., a connector and driver circuitry) to which a display device 3006 may be coupled. In another set of examples, the electrical device 3000 may not include an audio input device 3024 or an audio output device 3008, but may include audio input or output device interface circuitry (e.g., connectors and supporting circuitry) to which an audio input device 3024 or audio output device 3008 may be coupled.

The electrical device 3000 may include one or more processor units 3002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 3002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 3000 may include a memory 3004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 3004 may include memory that is located on the same integrated circuit die as the processor unit 3002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 3000 can comprise one or more processor units 3002 that are heterogeneous or asymmetric to another processor unit 3002 in the electrical device 3000. There can be a variety of differences between the processing units 3002 in a system in terms of a spectrum of metrics of merit including architectural, microarchitectural, thermal, power consumption characteristics, and the like. These differences can effectively manifest themselves as asymmetry and heterogeneity among the processor units 3002 in the electrical device 3000.

In some embodiments, the electrical device 3000 may include a communication component 3012 (e.g., one or more communication components). For example, the communication component 3012 can manage wireless communications for the transfer of data to and from the electrical device 3000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 3012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 3012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 3012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 3012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 3012 may operate in accordance with other wireless protocols in other embodiments. The electrical device 3000 may include an antenna 3022 to facilitate wireless communications and/or to receive other wireless communications (such as AM or FM radio transmissions).

In some embodiments, the communication component 3012 may manage wired communications, such as electrical, optical, or any other suitable communication protocols (e.g., IEEE 802.3 Ethernet standards). As noted above, the communication component 3012 may include multiple communication components. For instance, a first communication component 3012 may be dedicated to shorter-range wireless communications such as Wi-Fi or Bluetooth, and a second communication component 3012 may be dedicated to longer-range wireless communications such as global positioning system (GPS), EDGE, GPRS, CDMA, WiMAX, LTE, EV-DO, or others. In some embodiments, a first communication component 3012 may be dedicated to wireless communications, and a second communication component 3012 may be dedicated to wired communications.

The electrical device 3000 may include battery/power circuitry 3014. The battery/power circuitry 3014 may include one or more energy storage devices (e.g., batteries or capacitors) and/or circuitry for coupling components of the electrical device 3000 to an energy source separate from the electrical device 3000 (e.g., AC line power).

The electrical device 3000 may include a display device 3006 (or corresponding interface circuitry, as discussed above). The display device 3006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 3000 may include an audio output device 3008 (or corresponding interface circuitry, as discussed above). The audio output device 3008 may include any embedded or wired or wirelessly connected external device that generates an audible indicator, such as speakers, headsets, or earbuds.

The electrical device 3000 may include an audio input device 3024 (or corresponding interface circuitry, as discussed above). The audio input device 3024 may include any embedded or wired or wirelessly connected device that generates a signal representative of a sound, such as microphones, microphone arrays, or digital instruments (e.g., instruments having a musical instrument digital interface (MIDI) output). The electrical device 3000 may include a Global Navigation Satellite System (GNSS) device 3018 (or corresponding interface circuitry, as discussed above), such as a Global Positioning System (GPS) device. The GNSS device 3018 may be in communication with a satellite-based system and may determine a geolocation of the electrical device 3000 based on information received from one or more GNSS satellites, as known in the art.

The electrical device 3000 may include an other output device 3010 (or corresponding interface circuitry, as discussed above). Examples of the other output device 3010 may include an audio codec, a video codec, a printer, a wired or wireless transmitter for providing information to other devices, or an additional storage device.

The electrical device 3000 may include an other input device 3020 (or corresponding interface circuitry, as discussed above). Examples of the other input device 3020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 3000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 3000 may be any other electronic device that processes data. In some embodiments, the electrical device 3000 may comprise multiple discrete physical components. Given the range of devices that the electrical device 3000 can be manifested as in various embodiments, in some embodiments, the electrical device 3000 can be referred to as a computing device or a computing system.

### EXAMPLES

Illustrative examples of the technologies disclosed herein are provided below. An embodiment of the technologies may include any one or more, and any combination of, the examples described below.

Example 1 includes an apparatus comprising a substrate comprising a glass core, the glass core having a top surface defined in a top plane and a bottom surface defined in a bottom plane, wherein a cavity is defined in the glass core, the cavity extending from the top plane to the bottom plane; an inductor disposed in the cavity, the inductor comprising a conductive via extending from the top plane to the bottom plane and a magnetic material; and a buffer material between the inductor and the glass core.

Example 2 includes the subject matter of Example 1, and wherein the magnetic material surrounds the conductive via at the top plane and the bottom plane, wherein the magnetic material is adjacent the conductive via.

Example 3 includes the subject matter of any of Examples 1 and 2, and wherein the conductive via comprises a non-conductive plug.

Example 4 includes the subject matter of any of Examples 1-3, and wherein the buffer material comprises an organic polymer.

Example 5 includes the subject matter of any of Examples 1-4, and wherein the buffer material accommodates a change in size of the glass core and/or the inductor in response to a temperature change.

Example 6 includes the subject matter of any of Examples 1-5, and wherein the apparatus comprises an integrated circuit component, wherein the integrated circuit component comprises the substrate, wherein the integrated circuit component comprises a fully integrated voltage regulator (FIVR), wherein the FIVR comprises the inductor.

Example 7 includes the subject matter of any of Examples 1-6, and further including a first plurality of build-up layers on top of the top surface of the glass core; a second plurality of build-up layers below the bottom surface of the glass core; and a semiconductor die adjacent the first plurality of build-up layers.

Example 8 includes the subject matter of any of Examples 1-7, and wherein the semiconductor die is a processor die.

Example 9 includes the subject matter of any of Examples 1-8, and wherein the semiconductor die is a memory die.

Example 10 includes the subject matter of any of Examples 1-9, and further including a second inductor disposed in the cavity, the second inductor comprising a second conductive via extending from the top plane to the bottom plane and a magnetic material.

Example 11 includes the subject matter of any of Examples 1-10, and wherein a second cavity is defined in the glass core, the second cavity extending from the top plane to the bottom plane, further comprising a second inductor disposed in the second cavity, the second inductor comprising a second conductive via extending from the top plane to the bottom plane and a magnetic material.

Example 12 includes the subject matter of any of Examples 1-11, and further including a first pad at a first end of the conductive via and a second pad at a second end of the conductive via opposite the first end, further comprising a third pad disposed above the glass core, wherein the third pad is between the top plane and a plane defined by the first pad.

Example 13 includes the subject matter of any of Examples 1-12, and wherein the magnetic material comprises a plurality of particles, the plurality of particles comprising iron or nickel or both.

Example 14 includes an apparatus comprising a substrate comprising a glass core, the glass core having a top surface defined in a top plane and a bottom surface defined in a bottom plane, wherein a cavity is defined in the glass core, the cavity extending from the top plane to the bottom plane; an inductor disposed in the cavity, the inductor comprising a conductive via extending from the top plane to the bottom plane and a magnetic material; and means for relieving stress between the inductor and the glass core.

Example 15 includes the subject matter of Example 14, and wherein the magnetic material surrounds the conductive via at the top plane and the bottom plane, wherein the magnetic material is adjacent the conductive via.

Example 16 includes the subject matter of any of Examples 14 and 15, and wherein the conductive via comprises a non-conductive plug.

Example 17 includes the subject matter of any of Examples 14-16, and wherein the means for relieving stress comprises an organic polymer.

Example 18 includes the subject matter of any of Examples 14-17, and wherein the means for relieving stress accommodates a change in size of the glass core and/or the inductor in response to a temperature change.

Example 19 includes the subject matter of any of Examples 14-18, and wherein the apparatus comprises an integrated circuit component, wherein the integrated circuit component comprises the substrate, wherein the integrated circuit component comprises a fully integrated voltage regulator (FIVR), wherein the FIVR comprises the inductor.

Example 20 includes the subject matter of any of Examples 14-19, and further including a first plurality of build-up layers on top of the top surface of the glass core; a second plurality of build-up layers below the bottom surface of the glass core; and a semiconductor die adjacent the first plurality of build-up layers.

Example 21 includes the subject matter of any of Examples 14-20, and wherein the semiconductor die is a processor die.

Example 22 includes the subject matter of any of Examples 14-21, and wherein the semiconductor die is a memory die.

Example 23 includes the subject matter of any of Examples 14-22, and further including a second inductor disposed in the cavity, the second inductor comprising a second conductive via extending from the top plane to the bottom plane and a magnetic material.

Example 24 includes the subject matter of any of Examples 14-23, and wherein a second cavity is defined in the glass core, the second cavity extending from the top plane to the bottom plane, further comprising a second inductor disposed in the second cavity, the second inductor comprising a second conductive via extending from the top plane to the bottom plane and a magnetic material.

Example 25 includes the subject matter of any of Examples 14-24, and further including a first pad at a first end of the conductive via and a second pad at a second end of the conductive via opposite the first end, further comprising a third pad disposed above the glass core, wherein the third pad is between the top plane and a plane defined by the first pad.

Example 26 includes the subject matter of any of Examples 14-25, and wherein the magnetic material comprises a plurality of particles, the plurality of particles comprising iron or nickel or both.

Example 27 includes a method comprising forming a through hole in a buffer material, the buffer material disposed in a cavity of a glass core, the glass core having a top surface defined in a top plane and a bottom surface defined in a bottom plane, wherein the cavity extends from the top plane to the bottom plane, wherein the through hole extends at least from the top plane to the bottom plane; and forming an inductor in the through hole, the inductor comprising a conductive via extending at least from the top plane to the bottom plane and a magnetic material.

Example 28 includes the subject matter of Example 27, and further including forming the cavity in the glass core, wherein forming the cavity comprises forming the glass core using laser induced deep etching; and depositing the buffer material within the cavity of the glass core.

Example 29 includes the subject matter of any of Examples 27 and 28, and wherein the magnetic material surrounds the conductive via at the top plane and the bottom plane, wherein the magnetic material is adjacent the conductive via.

Example 30 includes the subject matter of any of Examples 27-29, and wherein the conductive via comprises a non-conductive plug.

Example 31 includes the subject matter of any of Examples 27-30, and wherein the buffer material comprises an organic polymer.

Example 32 includes the subject matter of any of Examples 27-31, and wherein the buffer material accommodates a change in size of the glass core and/or the inductor in response to a temperature change.

Example 33 includes the subject matter of any of Examples 27-32, and further including forming a fully integrated voltage regulator (FIVR) on the substrate, wherein the FIVR comprises the inductor.

Example 34 includes the subject matter of any of Examples 27-33, and further including forming a first plurality of build-up layers on top of the top surface of the glass core; forming a second plurality of build-up layers below the bottom surface of the glass core; and positioning a semiconductor die adjacent the first plurality of build-up layers.

Example 35 includes the subject matter of any of Examples 27-34, and wherein the semiconductor die is a processor die.

Example 36 includes the subject matter of any of Examples 27-35, and wherein the semiconductor die is a memory die.

Example 37 includes the subject matter of any of Examples 27-36, and further including a second inductor in the through hole, the second inductor comprising a second conductive via extending from the top plane to the bottom plane and a magnetic material.

Example 38 includes the subject matter of any of Examples 27-37, and wherein a second cavity is defined in the glass core, the second cavity extending from the top plane to the bottom plane, wherein the second cavity extends from the top plane to the bottom plane, forming a second through hole in the buffer material in the second cavity, wherein the second through hole extends at least from the top plane to the bottom plane; forming a second inductor in the second through hole, the second inductor comprising a second conductive via extending at least from the top plane to the bottom plane and a magnetic material.

Example 39 includes the subject matter of any of Examples 27-38, and further including forming a first pad at a first end of the conductive via and a second pad at a second end of the conductive via opposite the first end, further comprising forming a third pad disposed above the glass core, wherein the third pad is between the top plane and a plane defined by the first pad.

Example 40 includes the subject matter of any of Examples 27-39, and wherein the magnetic material comprises a plurality of particles, the plurality of particles comprising iron or nickel or both.

1. An apparatus comprising:
a substrate comprising a glass core, the glass core having a top surface defined in a top plane and a bottom surface defined in a bottom plane, wherein a cavity is defined in the glass core, the cavity extending from the top plane to the bottom plane;
an inductor disposed in the cavity, the inductor comprising a conductive via extending from the top plane to the bottom plane and a magnetic material; and
a buffer material between the inductor and the glass core.

2. The apparatus of claim 1, wherein the magnetic material surrounds the conductive via at the top plane and the bottom plane, wherein the magnetic material is adjacent the conductive via.

3. The apparatus of claim 2, wherein the conductive via comprises a non-conductive plug.

4. The apparatus of claim 1, wherein the buffer material comprises an organic polymer.

5. The apparatus of claim 4, wherein the buffer material accommodates a change in size of the glass core and/or the inductor in response to a temperature change.

6. The apparatus of claim 1, wherein the apparatus comprises an integrated circuit component, wherein the integrated circuit component comprises the substrate, wherein the integrated circuit component comprises a fully integrated voltage regulator (FIVR), wherein the FIVR comprises the inductor.

7. The apparatus of claim 1, further comprising:
a first plurality of build-up layers on top of the top surface of the glass core;
a second plurality of build-up layers below the bottom surface of the glass core; and
a semiconductor die adjacent the first plurality of build-up layers.

8. The apparatus of claim 7, wherein the semiconductor die is a processor die.

9. The apparatus of claim 1, further comprising a second inductor disposed in the cavity, the second inductor comprising a second conductive via extending from the top plane to the bottom plane and a magnetic material.

10. The apparatus of claim 1, wherein a second cavity is defined in the glass core, the second cavity extending from the top plane to the bottom plane,
further comprising a second inductor disposed in the second cavity, the second inductor comprising a second conductive via extending from the top plane to the bottom plane and a magnetic material.

11. The apparatus of claim 1, further comprising a first pad at a first end of the conductive via and a second pad at a second end of the conductive via opposite the first end, further comprising a third pad disposed above the glass core, wherein the third pad is between the top plane and a plane defined by the first pad.

12. The apparatus of claim 1, wherein the magnetic material comprises a plurality of particles, the plurality of particles comprising iron or nickel or both.

13. An apparatus comprising:
a substrate comprising a glass core, the glass core having a top surface defined in a top plane and a bottom surface defined in a bottom plane, wherein a cavity is defined in the glass core, the cavity extending from the top plane to the bottom plane;
an inductor disposed in the cavity, the inductor comprising a conductive via extending from the top plane to the bottom plane and a magnetic material; and
means for relieving stress between the inductor and the glass core.

14. The apparatus of claim 13, wherein the magnetic material surrounds the conductive via at the top plane and the bottom plane, wherein the magnetic material is adjacent the conductive via.

15. The apparatus of claim 14, wherein the conductive via comprises a non-conductive plug.

16. The apparatus of claim 13, wherein the means for relieving stress comprises an organic polymer.

17. The apparatus of claim 16, wherein the means for relieving stress accommodates a change in size of the glass core and/or the inductor in response to a temperature change.

18. A method comprising:
forming a through hole in a buffer material, the buffer material disposed in a cavity of a glass core, the glass core having a top surface defined in a top plane and a bottom surface defined in a bottom plane, wherein the cavity extends from the top plane to the bottom plane, wherein the through hole extends at least from the top plane to the bottom plane; and
forming an inductor in the through hole, the inductor comprising a conductive via extending at least from the top plane to the bottom plane and a magnetic material.

19. The method of claim 18, further comprising:
forming the cavity in the glass core, wherein forming the cavity comprises forming the glass core using laser induced deep etching; and
depositing the buffer material within the cavity of the glass core.

20. The method of claim 18, further comprising:
forming a first plurality of build-up layers on top of the top surface of the glass core;
forming a second plurality of build-up layers below the bottom surface of the glass core; and
positioning a semiconductor die adjacent the first plurality of build-up layers.
